(19) United States
(12) Patent Application Publication
(10) Pub. No.: US 2025/0107290 A1
(43) Pub. Date: Mar. 27, 2025

(54) LIGHT EMITTING DEVICE

(71) Applicant: SEOUL SEMICONDUCTOR CO., LTD., Ansan-si (KR)

(72) Inventors: Jae Hoon LEE, Ansan-si (KR); Do Kwang LEE, Ansan-si (KR); Hyung Keun LEE, Ansan-si (KR)

(21) Appl. No.: 18/897,321

(22) Filed: Sep. 26, 2024

Related U.S. Application Data
(60) Provisional application No. 63/585,628, filed on Sep. 27, 2023.
(60) Provisional application No. 63/589,056, filed on Oct. 10, 2023.

(51) Int. Cl. H01L 33/50; H01L 25/075; H01L 33/60

(52) U.S. Cl. CPC H10H 20/8514; H01L 25/0753; H10H 20/856

(57) ABSTRACT

A light emitting device includes light emitting diode chip, a substrate forming a mounting region where the light emitting diode chip is mounted, and a wavelength converter disposed on an upper surface of the light emitting diode chip, wherein the wavelength converter includes a plurality of wavelength conversion layers, at least some of the plurality of wavelength conversion layers being disposed on the same plane.

### CROSS-REFERENCE TO RELATED APPLICATIONS

This application claims priority to and the benefit of U.S. Provisional Application No. 63/585,628, filed on Sep. 27, 2023, and U.S. Provisional Application No. 63/589,056, filed on Oct. 10, 2023. The aforementioned applications are incorporated herein by reference in their entireties.

### TECHNICAL FIELD

Some implementations of the disclosed technology relate to light emitting devices, including a light emitting device comprising a light emitting diode chip and a wavelength converter.

### BACKGROUND

A light emitting diode (LED) is a semiconductor device that can emit light of various colors through a P-N junction. Recently, with the development of blue and UV light emitting diodes have been manufactured using nitrides with excellent physical and chemical properties, it has become possible to produce white light or other monochromatic light by combining these blue or UV light emitting diodes with phosphor materials, thereby expanding the application range of light emitting diodes.

White light can be realized using red (R), green (G) and blue (B) light emitting diodes simultaneously allowing the light emitted from each to overlap, but alternatively, white light can be realized through the combination of a light emitting diode and phosphor materials, allowing white light to be realized with a single light emitting diode.

### SUMMARY

Various implementations of the disclosed technology provide a light emitting device with excellent color reproducibility, improved chromatic aberration, and a reduced defect rate.

In accordance with one embodiment of the disclosed technology, a light emitting device includes a light emitter, a substrate forming a mounting region where the light emitter is mounted, and a wavelength converter disposed on an upper surface of the light emitter.

In some implementations, the wavelength converter may include a plurality of wavelength conversion layers. In some implementations, the light emitter may include a light emitting diode chip or may include a plurality of light emitting diode chips. In some implementations, each of the plurality of light emitting-diode chips may be individually operable. In some implementations, at least some of the plurality of wavelength conversion layers may be disposed on the same plane. In some implementations, the wavelength conversion layers may be arranged such that they are spaced apart in a plane.

In some implementations, the light emitting device may further include a film adhesive layer disposed between the plurality of wavelength conversion layers and the light emitting diode chip, which adheres the plurality of wavelength conversion layers to the light emitting diode chip. In some implementations, the light emitting device may further include an upper light controller formed in a space between adjacent wavelength conversion layers. In some implementations, an upper surface of the upper light controller may include a concave surface. In some implementations, the light emitting device may further include a side light controller formed on a side surface of the light emitting diode chip.

In some implementations, the wavelength conversion layers may form an extension protruding beyond an outer periphery of the light emitting diode chip. In some implementations, the side light controller may be formed in a space between the extension of the wavelength conversion layer and the side surface of the light emitting diode chip. In some implementations, the side light controller may have a variable width which varies from top to bottom. In some implementations, the side light controller may form an inclined surface on its outward side surface. In some implementations, the light emitting device may further include a lens layer covering the light emitting diode chip, the substrate, and the wavelength converter.

In some implementations, the light emitting device may further include a side reflector formed on a side surface of the light emitting diode chip to reflect light emitted from the side surface of the light emitting diode chip. In some implementations, a maximum height of the side reflector from an upper surface of the substrate may be between a height from the upper surface of the substrate to a lower surface of the wavelength converter and a height from the upper surface of the substrate to an upper surface of the wavelength converter.

In some implementations, the light emitting device may further include a sidewall defining a cavity for mounting the light emitting diode chip. In some implementations, a minimum thickness of the wavelength conversion layers may be at least twice a particle size of phosphor particles having the largest particle size among phosphor particles disposed in any one region of the wavelength conversion layer. In some implementations, a maximum thickness of the wavelength converter may be no greater than twice a maximum thickness of the light emitter where the wavelength converter is disposed. In some implementations, the wavelength conversion layers may have different color coordinates.

In some implementations, each of the plurality of wavelength conversion layers may convert the light emitted from the light emitter into light having specific CIE (x, y) coordinates distinct each other. In some implementations, the wavelength converter may represent the combined color coordinates of the wavelength conversion layers. In some implementations, first excitation light and second excitation light emitted respectively from at least two of the plurality of wavelength conversion layers may have different color coordinates. In some implementations, the first excitation light and the second excitation light may have a color temperature of K=449n³+3525n²−6823.3n+5520.33, where

$$n = \frac{( x - 0.332 )}{( y - 0.1858 )} .$$

In some implementations, a difference between a first K value of the first excitation light and a second K value of the second excitation light may be less than or equal to 1,000.

In accordance with another embodiment of the disclosed technology, a light emitting device includes: a light emitter; a substrate forming a mounting region where the light emitter is mounted; and a wavelength converter disposed on an upper surface of the light emitter, wherein the wavelength converter includes a plurality of wavelength conversion layers forming an extension protruding beyond an outer periphery of the light emitter.

In some implementations, the light emitter may include a light emitting diode chip or may include a plurality of light emitting diode chips. In some implementations, each of the plurality of light emitting diode chips may be individually operable. In some implementations, at least some of the plurality of wavelength conversion layers may be disposed on the same plane. In some implementations, the wavelength conversion layers may be arranged such that they are spaced apart in a plane.

In some implementations, the light emitting device may further include a film adhesive layer disposed between the plurality of wavelength conversion layers and the light emitting diode chip, which adheres the plurality of wavelength conversion layers to the light emitting diode chip. In some implementations, the light emitting device may further include an upper light controller formed in a space formed between adjacent wavelength conversion layers. In some implementations, an upper surface of the upper light controller may include a concave surface. In some implementations, the light emitting device may further include a side light controller formed on a side surface of the light emitting diode chip.

In some implementations, the side light controller may be formed in a space between an extension of the wavelength conversion layers and the side surface of the light emitting diode chip. In some implementations, the side light controller may have a variable width which varies from top to bottom. In some implementations, the side light controller may form an inclined surface on its outward side surface. In some implementations, the light emitting device may further include a lens layer covering the light emitting diode chip, the substrate, and the wavelength converter.

In some implementations, the light emitting device may further include a side reflector formed on a side surface of the light emitting diode chip to reflect light emitted from the side surface of the light emitting diode chip. In some implementations, a maximum height of the side reflector from an upper surface of the substrate may be between a height from the upper surface of the substrate to a lower surface of the wavelength converter and a height from the upper surface of the substrate to an upper surface of the wavelength converter.

In some implementations, the light emitting device may further include a sidewall forming a cavity for mounting the light emitting diode chip. In some implementations, a minimum thickness of the wavelength conversion layers may be at least twice a particle size of phosphor particles having the largest particle size among phosphor particles disposed in any one region of the wavelength conversion layer. In some implementations, a maximum thickness of the wavelength converter may be no greater than twice a maximum thickness of the light emitter where the wavelength converter is disposed. In some implementations, the wavelength conversion layers may have different color coordinates.

In some implementations, each of the plurality of wavelength conversion layers may convert the light emitted from the light emitter into light having specific CIE (x, y) coordinates distinct each other. In some implementations, the wavelength converter may represent the combined color coordinates of the wavelength conversion layers. In some implementations, first excitation light and second excitation light emitted respectively from at least two of the plurality of wavelength conversion layers may have different color coordinates. In some implementations, the first excitation light and the second excitation light have a color temperature of K=449n³+3525n²−6823.3n+5520.33, where

$$n = \frac{( x - 0.332 )}{( y - 0.1858 )} .$$

In some implementations, a difference between a first K value of the first excitation light and a second K value of the second excitation light may be less than or equal to 1,000.

In accordance with a further embodiment of the disclosed technology, a light emitting device includes: a light emitter; a substrate forming a mounting region where the light emitter is mounted; and a wavelength converter disposed on an upper surface of the light emitter, wherein the wavelength converter includes a plurality of wavelength conversion layers having different color coordinates.

In some implementations, first excitation light and second excitation light emitted respectively from at least two of the plurality of wavelength conversion layers may have different color coordinates. In some implementations, the first excitation light and the second excitation light may have a color temperature of K=449n³+3525n²−6823.3n+5520.33, where

$$n = \frac{( x - 0.332 )}{( y - 0.1858 )} .$$

In some implementations, a difference between a first K value of the first excitation light and a second K value of the second excitation light may be less than or equal to 1,000.

In some implementations, the wavelength converter may represent the combined color coordinates of the wavelength conversion layers. In some implementations, the plurality of wavelength conversion layers may have different color coordinates. In some implementations, each of the plurality of wavelength conversion layers may convert the light emitted from the light emitter into light having specific CIE (x, y) coordinates distinct each other. In some implementations, the light emitter may include a light emitting diode chip, and may include a plurality of light emitting diode chips. In some implementations, each of the plurality of light emitting diode chips may be individually operable.

In some implementations, at least some of the plurality of wavelength conversion layers may be disposed on the same plane. In some implementations, the wavelength conversion layers may be arranged such that they are spaced apart in a plane. In some implementations, the light emitting device may further include a film adhesive layer disposed between the plurality of wavelength conversion layers and the light emitting diode chip, which adheres the plurality of wavelength conversion layers to the light emitting diode chip.

In some implementations, the light emitting device may further include an upper light controller formed in a space formed between adjacent wavelength conversion layers. In some implementations, an upper surface of the upper light controller may include a concave surface. In some implementations, the light emitting device may further include a side light controller formed on a side surface of the light emitting diode chip. In some implementations, the side light controller may be formed in a space between an extension of the wavelength conversion layers and the side surface of the light emitting diode chip.

In some implementations, the side light controller may have a variable width which varies from top to bottom. In some implementations, the side light controller may form an inclined surface on its outward side surface. In some implementations, the light emitting device may further include a lens layer covering the light emitting diode chip, the substrate, and the wavelength converter. In some implementations, the light emitting device may further include a side reflector formed on a side surface of the light emitting diode chip to reflect light emitted from the side surface of the light emitting diode chip.

In some implementations, a maximum height of the side reflector from an upper surface of the substrate may be between a height from the upper surface of the substrate to a lower surface of the wavelength converter and a height from the upper surface of the substrate to an upper surface of the wavelength converter. In some implementations, the light emitting device may further include a sidewall forming a cavity for mounting the light emitting diode chip. In some implementations, a minimum thickness of the wavelength conversion layers may be at least twice a particle size of phosphor particles having the largest particle size among phosphor particles disposed in any one region of the wavelength conversion layer. In some implementations, a maximum thickness of the wavelength converter may be no greater than twice a maximum thickness of the light emitter in which the wavelength converter is disposed.

In accordance with still another embodiment of the disclosed technology, a light emitting device includes: a light emitter; a substrate forming a mounting region where the light emitter is mounted; and a wavelength converter disposed on an upper surface of the light emitter, wherein the wavelength converter includes a plurality of wavelength conversion layers each being capable of exciting light emitted from the light emitter into light having specific CIE (x, y) coordinates distinct each other. The excitation light may have a color temperature of K=449n³+3525n²−6823.3n+5520.33, where

$$n = \frac{( x - 0.332 )}{( y - 0.1858 )} .$$

In some implementations, the excitation light emitted from the wavelength conversion layers may have different K values and a difference between the K values may be less than or equal to 1,000. In some implementations, first excitation light and second excitation light emitted respectively from at least two of the plurality of wavelength conversion layers may have different color coordinates. In some implementations, the first excitation light and the second excitation light may have a color temperature of K=449n³+3525n²−6823.3n+5520.33, where

$$n = \frac{( x - 0.332 )}{( y - 0.1858 )} .$$

In some implementations, a difference between a first K value of the first excitation light and a second K value of the second excitation light may be less than or equal to 1,000. In some implementations, the light emitter may include a light emitting diode chip or may include a plurality of light emitting diode chips. In some implementations, each of the plurality of light emitting diode chips may be individually operable.

In some implementations, at least some of the plurality of wavelength conversion layers may be disposed on the same plane. In some implementations, the wavelength conversion layers may be arranged such that they are spaced apart in a plane. In some implementations, the light emitting device may further include a film adhesive layer disposed between the plurality of wavelength conversion layers and the light emitting diode chip, which adheres the plurality of wavelength conversion layers to the light emitting diode chip.

In some implementations, the light emitting device may further include an upper light controller formed in a space formed between adjacent wavelength conversion layers. In some implementations, the upper surface of the upper light controller may include a concave surface. In some implementations, the light emitting device may further include a side light controller formed on a side surface of the light emitting diode chip. In some implementations, the wavelength conversion layers may form an extension protruding beyond an outer periphery of the light emitting diode chip. In some implementations, the side light controller may be formed in a space between the extension of the wavelength conversion layers and a side surface of the light emitting diode chip.

In some implementations, the side light controller may have a variable width which varies from top to bottom. In some implementations, the side light controller may form an inclined surface on its outward side surface. In some implementations, the light emitting device may further include a lens layer covering the light emitting diode chip, the substrate, and the wavelength converter. In some implementations, the light emitting device may further include a side reflector formed on a side surface of the light emitting diode chip to reflect light emitted from the side surface of the light emitting diode chip. In some implementations, a maximum height of the side reflector from an upper surface of the substrate may be between a height from the upper surface of the substrate to a lower surface of the wavelength converter and a height from the upper surface of the substrate to an upper surface of the wavelength converter.

In some implementations, the light emitting device may further include a sidewall forming a cavity for mounting the light emitting diode chip. In some implementations, a minimum thickness of the wavelength conversion layers may be at least to twice a particle size of phosphor particles having the largest particle size among phosphor particles disposed in any one region of the wavelength conversion layer. In some implementations, a maximum thickness of the wavelength converter may be no greater than twice a maximum thickness of the light emitter where the wavelength converter is disposed. In some implementations, the wavelength conversion layers can have different color coordinates. In some implementations, the wavelength converter may represent the combined color coordinates of the wavelength conversion layers.

Embodiments of the disclosed technology may provide a light emitting device that has excellent color reproduction, reduced chromatic aberration, and reduced defect rate.

Embodiments of the disclosed technology may provide a light emitting device with improved light extraction efficiency to emit a large quantity of light. Embodiments of the disclosed technology may provide a light emitting device with enhanced reliability. Embodiments of the disclosed technology may provide a light emitting device with improved chromatic aberration depending on beam angle. Embodiments of the disclosed technology may provide a light emitting device in which the chromatic aberration according to the beam angle changes continuously without abrupt changes.

### BRIEF DESCRIPTION OF DRAWINGS

FIG. 1 is a plan view of a fluorescent batch applied to a light emitting device according to one embodiment of the disclosed technology.

FIG. 2 is a cross-sectional view of an example of a typical light emitting device.

FIG. 3A is a partial plan view of a light emitting device according to one embodiment of the disclosed technology.

FIG. 3B is a plan view of a modification of the light emitting device shown in FIG. 3A.

FIG. 4 is a plan view of another modification of the light emitting device shown in FIG. 3A.

FIG. 5A and FIG. 5B are plan views showing a partial configuration of a light emitting device in which a light emitter includes two light emitting diode chips.

FIG. 6A and FIG. 6B are plan views showing a partial configuration of a light emitting device in which a light emitter includes three light emitting diode chips.

FIG. 7 is a cross-sectional view of a light emitting device according to another embodiment of the disclosed technology.

FIG. 8 is a cross-sectional view of a light emitting device according to a further embodiment of the disclosed technology.

FIG. 9 is a cross-sectional view of a modification of the light emitting device shown in FIG. 8.

FIG. 10 is a cross-sectional view of a modification of the light emitting device shown in FIG. 9.

FIG. 11A and FIG. 11B are cross-sectional views of a light emitting device according to still another embodiment of the disclosed technology.

FIG. 12 is a color coordinate graph showing a distribution of CIE (x, y) coordinates for two different wavelength conversion layers.

FIG. 13 is a color coordinate graph showing a distribution of CIE coordinates of a light emitting device including the wavelength conversion layers shown in FIG. 12.

FIG. 14A and FIG. 14B are graphs showing relative frequency of the color coordinates (x, y) of two different wavelength conversion layers.

FIG. 15A and FIG. 15B are graphs showing relative frequency of the color coordinates (x, y) of the light emitting device including the wavelength conversion layers shown in FIG. 14A.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Embodiments of the disclosed technology provide a light emitting device 100 including: at least one light emitter; a substrate 120 forming a mounting region where the light emitter is mounted, and a wavelength converter 130 disposed on an upper surface of the light emitter. Hereinafter, exemplary embodiments of the disclosed technology will be described in more detail with reference to the accompanying drawings.

The light emitter may include at least one light emitting diode chip 110 or a plurality of light emitting diode chips 110. In the structure where the light emitter includes a plurality of light emitting diode chips 110, at least two light emitting diode chips 110 may have different dominant wavelengths and a wavelength deviation of the different dominant wavelengths may be less than or equal to 20 nm.

The light emitting diode chip 110 is adapted to generate light and may have various configurations. The light emitting diode chip 110 may include semiconductor layers formed on a growth substrate.

Here, the growth substrate may include any substrates so long as the substrate allows growth of nitride semiconductors thereon, and may include, for example, a heterogeneous substrate, such as a sapphire substrate, a silicon substrate, a silicon carbide substrate, a spinel substrate, or others, or a homogeneous substrate, such as a gallium nitride substrate, an aluminum nitride substrate, or others.

The semiconductor layers constituting the light emitting diode chip 110 may include a first conductivity type semiconductor layer, an active layer, and a second conductivity type semiconductor layer, in which the first conductivity type semiconductor layer is disposed on the second conductivity type semiconductor layer and the active layer is interposed between the first and second conductivity type semiconductor layers.

The first conductivity type semiconductor layer may be a semiconductor layer grown on one surface of the growth substrate and a buffer layer may be further formed between the first conductivity type semiconductor layer and the growth substrate. The buffer layer may include a nitride semiconductor, such as GaN, and may be grown by MOCVD. The buffer layer can improve crystallinity of the semiconductor layers grown on the growth substrate in subsequent processes and can act as a seed layer for growth of nitride type semiconductor layers on a heterogeneous substrate.

The first conductivity type semiconductor layer may include a nitride semiconductor, such as (Al, Ga, In) N, and may be formed by growth on the growth substrate through a technique, such as MOCVD, MBE, HVPE, or others. In addition, the first conductivity type semiconductor layer may be doped with at least one type of n-type dopant, such as Si, C, Ge, Sn, Te, Pb, or others, to have n-type conductivity. Alternatively, the first conductivity type semiconductor layer may be doped with a p-type dopant to become an opposite conductivity type.

In a structure wherein the first conductivity type semiconductor layer is composed of multiple layers, the first conductivity type semiconductor layer may include superlattice layers. The first conductivity type semiconductor layer may further include a contact layer, a modulation doping layer, an electron implantation layer, or others.

The active layer is a light emitting layer formed on the first conductivity type semiconductor layer and may have a multi-quantum well (MQW) structure. The active layer may include a nitride semiconductor, such as (Al, Ga, In) N, and may be grown on the first conductivity type semiconductor layer by a technique, such as MOCVD, MBE, or HVPE.

The wavelength of light emitted from the active layer may be adjusted by controlling the composition ratio of a nitride semiconductor layer in a well layer. Here, the well layer may include a nitride semiconductor containing indium (In).

The second conductivity type semiconductor layer may be a semiconductor layer formed on the active layer.

The second conductivity type semiconductor layer may include a nitride semiconductor, such as (Al, Ga, In) N, and may be grown by a technique, such as MOCVD, MBE, or HVPE.

The second conductivity type semiconductor layer may be doped to become a conductivity type opposite to the conductivity type of the first conductivity type semiconductor layer. For example, the second conductivity type semiconductor layer may be doped with p-type dopants, such as Mg.

The second conductivity type semiconductor layer may have a monolayer structure having a composition, such as p-GaN, and may further include an AlGaN layer therein, without being limited thereto.

It will be apparent that the light emitter may be configured in various ways and may be modified into various structures including a flip-chip type light emitting diode, a vertical type light emitting diode, a horizontal type light emitting diode, or others.

Further, the light emitter may include an LED chip that generates light of various colors with various wavelengths, such as blue light, UV light, or others, and is not limited to an LED chip emitting light in a particular wavelength range.

The substrate 120 may have various configurations to act as a circuit board forming a mounting region where the light emitting diode chip 110 is mounted, and may include a lead frame for packaging the light emitting diode chip 110.

The substrate 120 is a circuit board having an upper surface on which at least one light emitting diode chip 110 is mounted, and may include an insulating layer, interconnections for electrical connection with the light emitting diode chip 110, and circuits for supplying electric power and driving the light emitting diode chip 110.

The substrate 120 may be formed of any substrate material capable of defining a mounting region where the light emitting diode chip 110 will be mounted. For example, the substrate 120 may be formed of alumina, quartz, calcium zirconate, forsterite, SiC, graphite, fused silica, mullite, cordierite, zirconia, beryllia, aluminum nitride, low temperature co-fired ceramics (LTCC), paper phenolic resins, or epoxy resins bonded to glass or paper, and may further include interconnections including metals and metal compounds, such as Cu, Al, Ag, Au, Ni, W, or others, on the insulating layer formed of polyimide (PI), bismaleimide/triazine (B/T), Teflon, or others.

An anode and a cathode may be formed on an upper surface of the substrate 120 corresponding to electrodes of the light emitting diode chip 110.

A chip-adhesive layer 190 may be interposed between the substrate 120 and the light emitting diode chip 110 to attach the light emitting diode chip 110 to the substrate 120. The chip-adhesive layer 190 may be formed by soldering or eutectic bonding.

The wavelength converter 130 is disposed on an upper surface of the light emitting diode chip 110 and converts light emitted from the light emitting diode chip 110 into excitation light to emit light of a different color. The wavelength converter 130 may have various configurations. For example, the wavelength converter 130 may be disposed on the light emitting diode chip 110 emitting blue light and may be configured to emit green, yellow and red light using a fraction of light emitted from the light emitting diode chip as an excitation source such that white light can be finally emitted from the light emitting device.

The wavelength converter 130 may be composed of fluorescent batches S1, S2, which may be prepared in the form of slurries by mixing a phosphor with a resin. Here, it is desirable that the resin mixed with the phosphor preferably have high hardness and good reliability. For example, the resin may have a Shore A hardness of about 50 or more or a Shore D hardness of about 30 or more, without being limited thereto.

In some implementations, the resin may include a transparent thermosetting resin, for example, silicone resins, epoxy resins, glass, glass ceramics, polyester resins, acrylic resins, urethane resins, Nylon resins, polyamide resins, polyimide resins, vinyl chloride resins, polycarbonate resins, polyethylene resins, Teflon resins, or polystyrene resins, polypropylene resins, polyolefin resins. The above materials are examples only and other implementations are also possible.

In some implementations, the slurry may be prepared by mixing a liquid epoxy resin with the phosphor, and may further include additives, such as a solvent, as needed, without being limited thereto. The slurry may further include a solid resin.

According to embodiments, the resin mixed with the phosphor may have reflectivity of, for example, about 1.4 to about 1.8, without being limited thereto.

In some implementations, the fluorescent batches S1, S2 may have various thicknesses in the range of about 15 μm to about 500 μm depending on embodiments, preferably a thickness of about 30 μm to about 150 μm. If the fluorescent sheets S1, S2 have too thin a thickness of less than about 30 μm, it is difficult for the phosphor to be uniformly distributed in a phosphor sheet 23, thereby making it difficult for the light emitting device 20 to emit white light, and if the fluorescent batches S1, S2 have too thick a thickness of greater than about 150 μm, light can be emitted from lateral sides of the fluorescent batches S1, S2 rather than from front sides of the fluorescent batches S1, S2, thereby reducing luminous intensity (cd). Accordingly, the minimum thickness of the fluorescent batches S1, S2 may be greater than or equal to twice the particle size of phosphor particles having the largest size among phosphor particles distributed in any one region of the fluorescent batches. In the example, the maximum thickness of the fluorescent batches S1, S2 may be less than or equal to twice the thickness of the light emitting diode chip 110.

In some implementations, the maximum thickness of the fluorescent batches S1, S2 may be less than or equal to twice the maximum thickness of the light emitting diode chip 110. Alternatively, the maximum thickness of the fluorescent batches S1, S2 may be less than or equal to twice the thickness of the substrate of the light emitting diode chip 110. Alternatively, the maximum thickness of the fluorescent batches S1, S2 may be less than or equal to twice the thickness of the substrate 120 on which the light emitting diode chip 110 is mounted.

In some implementations, the phosphor mixed with the resin may be not only a single type of phosphor, but also a mixture of multiple types of phosphors, as needed.

The phosphor may include any types of phosphors known in the art. In some implementations, the phosphor may include, for example, (Ba, Sr, Ca)₂SiO₄: Eu²⁺, YAG((Y, Gd)₃(Al, Ga)₅O₁₂: Ce³⁺), TAG((Tb, Gd)₃(Al, Ga)₅O₁₂: Ce³⁺), (Ba, Sr, Ca)₃SiO₅: Eu²⁺, (Ba, Sr, Ca)MgSi₂O₆: Eu²⁺, Mn²⁺, (Ba, Sr, Ca)₃MgSi₂O₈: Eu²⁺, Mn²⁺ and (Ba, Sr, Ca) MgSiO₄:Eu²⁺, Mn²⁺, or fluoride-based phosphors represented by A₂MF₆: Mn⁴⁺, where A may be Li, Na, K, Ba, Rb, Cs, Mg, Ca, Se, or Zn and M may include Ti, Si, Zr, Sn, or Ge, without being limited thereto.

The fluorescent batches S1, S2 are manufactured using the slurry, which is the mixture of the resin and the phosphor, and may be manufactured by press forming the slurry into a sheet or lens shape in a mold under constant pressure. However, it should be understood that other implementations are possible and the fluorescent batches S1, S2 may also be formed by various manufacturing processes, such as extrusion molding, doctor-blade coating, and the like.

In some implementations, the slurry may be fed into an extruder, in which the slurry is extruded from a mold to form the fluorescent batches S1, S2, or may be poured onto a floor such that a blade designed to maintain a certain distance from the floor can pass over the slurry to form the fluorescent batches S1, S2 having a uniform thickness. Alternatively, the slurry may be applied to the floor or substrate to have a shape formed by viscosity of the slurry, for example, such that some regions are flat and some regions have a curvature.

The manufactured fluorescent batches S1, S2 may be cut to a desired size and shape through, for example, a sawing or scribing process, and may be applied to predetermined regions. The fluorescent batches S1, S2 may be attached to or deposited on an upper surface of the light emitting diode chip 110 to form individual wavelength conversion layers 130a, 130b, 130c each having a predetermined size.

However, the manufactured fluorescent batches S1, S2 have uneven distribution or density of the phosphor from batch to batch, from lot to lot, or depending on the location inside the sheet, causing irregular luminance, poor color reproduction, and increase in defect rate.

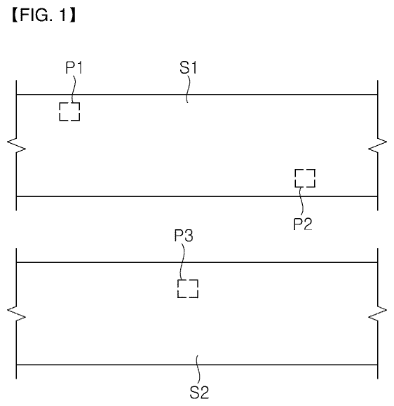

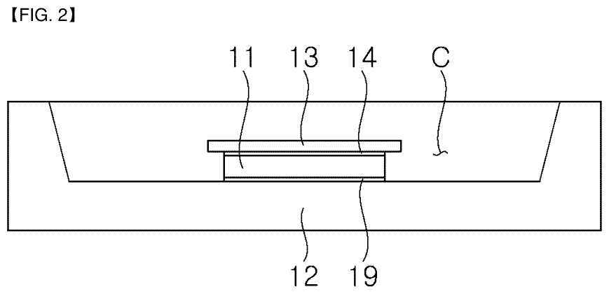

In some implementations, referring to FIG. 1, a first region P1 of a first fluorescent batch S1 has a different phosphor distribution or density and thickness from a second region P2 of a second fluorescent batch S2. Likewise, the phosphor distribution or density and thickness in a third region P3 of the second fluorescent batch S2, which is a different batch from the first fluorescent batch S1, will be different from those of the first fluorescent batch S1.

As a result, the wavelength conversion layers 130a, 130b, 130c formed from the fluorescent batches S1, S2 have different CIE x or CIE y color coordinates and, as the color coordinates are distributed in a wider range, the wavelength conversion layers 130a, 130b, 130c have different light emitting characteristics, causing uneven color coordinate performance or increase in deviation of color coordinate performance of each of the light emitting devices 100 to which the wavelength conversion layers 130a, 130b, 130c are applied.

In particular, since the coefficient n of the correlated color temperature (CCT) changes according to the CIE (x, y) color coordinates, as shown in Equation 1, a difference in color coordinates between the wavelength conversion layers 130a, 130b, 130c can cause a large difference in color temperature between light emitters, thereby causing deterioration in color uniformity of the light emitting device.

$$K = 449 {n}^{3} + 3525 {n}^{2} - 6823.3 n + 55 20.33 \qquad [ Equation 1 ]$$

K: Color temperature
n: coefficient
x, y: CIE (x, y) color coordinates

Considering this problem, the light emitting devices according to embodiments of the disclosed technology have a structure where a plurality of wavelength conversion layers 130a, 130b, 130c is disposed on a single light emitter rather than a structure where one wavelength conversion layer 130a, 130b or 130c is disposed on a single light emitter.

Each of the plurality of wavelength conversion layers 130a, 130b, 130c may excite light emitted from the light emitter 120 into the light having specific CIE (x, y) coordinates distinct each other. In Equation 1, the excitation light converted by the wavelength conversion layers 130a, 130b, 130c may have different K values and a difference between the K values may be 1,000 or less. Accordingly, the wavelength converter 130 may represent the combined color coordinates of the wavelength conversion layers 130a, 130b, 130c.

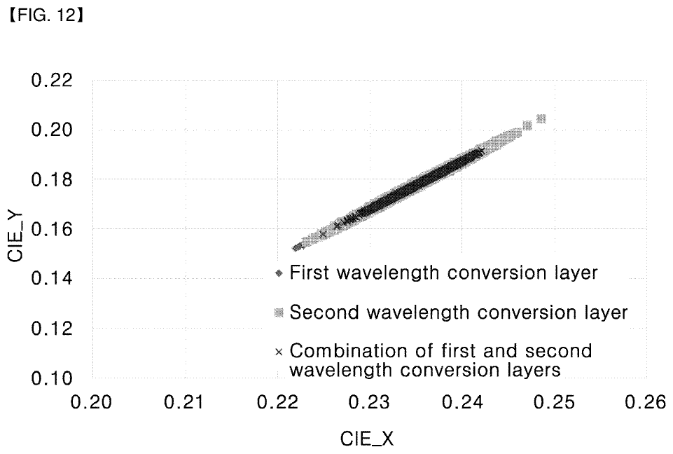

FIG. 12 is a graph illustrating a distribution of CIE (x, y) coordinates of a film with target CIE (x, y) center coordinates (0.23, 0.18) as an example. FIG. 12 shows a CIE (x, y) color coordinate distribution of the wavelength conversion layers 130a, 130b, 130c formed from the first fluorescence batch S1, a CIE (x, y) color coordinate distribution of the wavelength conversion layers 130a, 130b, 130c formed from the second fluorescence batch S2, and a CIE (x, y) color coordinate distribution of a random combination of two wavelength conversion layers of the wavelength conversion layers 130a, 130b, 130c formed from the first fluorescence batch S1 and the second fluorescence batch S2. It should be understood that the CIE (x, y) color coordinate distributions shown in FIG. 12 are provided by way of example and are experimental examples, and embodiments of the disclosed technology are not limited to the CIE (x, y) color coordinate distributions shown in FIG. 12.

Referring to FIG. 12, it can be seen that the CIE (x, y) color coordinates of each of the fluorescent batches S1, S2 are unevenly distributed over a very wide range, whereas the CIE (x, y) color coordinate distribution of the combination of the two wavelength conversion layers 130a, 130b, 130c is narrowed to the range of median coordinates of the wavelength conversion layers, thereby improving uniformity of luminous characteristics. For example, the standard deviation of the CIE x coordinates is 0.0034 for the first wavelength conversion layer and 0.0033 for the second wavelength conversion layer, whereas the standard deviation of the CIE x coordinates is reduced to 0.0023 for the combination of the first and second wavelength conversion layers. In other words, in the structure where the first wavelength conversion layer 130a with a relatively low x coordinate (x coordinate having a relatively small value) is combined with the second wavelength conversion layer 130b with a relatively high x coordinate (x coordinate having a relatively great value), the CIE x coordinate of the combined wavelength conversion layers can have a value or coordinate located between the CIE x coordinates of the first wavelength conversion layer 130a and the second wavelength conversion layer 130b. Thus, the combination of the first wavelength conversion layer 130a and the second wavelength conversion layer 130b can achieve the same effect as application of a wavelength conversion layer with a color coordinate higher than or equal to the first wavelength conversion layer 130a and lower than or equal to the second wavelength conversion layer 130b. In addition, the standard deviation of the CIE y coordinates is 0.0066 for the first wavelength conversion layer 130a and 0.0065 for the second wavelength conversion layer 130b, whereas the standard deviation of the CIE y coordinates is reduced to 0.0045 for the combination of the first and second wavelength conversion layer 130bs. In other words, in the structure where the first wavelength conversion layer 130a with a relatively low y coordinate (y coordinate having a relatively small value) is combined with the second wavelength conversion layer 130b with a relatively high y coordinate (y coordinate having a relatively great value) in the CIE y coordinate, the CIE y coordinate of the combined wavelength conversion layers can have a value or coordinate located between the CIE y coordinates of the first wavelength conversion layer 130a and the second wavelength conversion layer 130b. In other words, the combination of the first wavelength conversion layer 130a and the second wavelength conversion layer 130b can achieve the same effect as application of a wavelength conversion layer with a color coordinate higher than or equal to the first wavelength conversion layer 130a and lower than or equal to the second wavelength conversion layer 130b. Here, for the K value obtained through the color coordinates of excitation light emitted from the first wavelength conversion layer 130a, the K value obtained through the color coordinates of excitation light emitted from the second wavelength conversion layer 130b, and the K value obtained through the color coordinate of excitation light emitted from the combination of the first and second wavelength conversion radars 130a, 130b, a deviation between the K values may be within a range of +1,000.

For example, the first excitation light and the second excitation light emitted from at least two of the plurality of wavelength conversion layers 130a, 130b, 130c may have different color coordinates.

The first excitation light and the second excitation light have a color temperature of K=449n³+3525n²−6823.3n+5520.33, where

$$n = \frac{( x - 0.332 )}{( y - 0.1858 )} .$$

Here, the difference between the first K value caused by the first excitation light and the second K value caused by the second excitation light may be less than or equal to 1,000.

In some implementations, combination of the first wavelength conversion layer 130a having a relatively low correlated color temperature (CCT) and the second wavelength conversion layer 130b having a relatively high correlated color temperature can provide a light emitting device having a correlated color temperature between the correlated color temperatures of the first wavelength conversion layer 130a and the second wavelength conversion layer 130b. Further, the combined wavelength conversion layers can have a correlated color temperature that is higher than or equal to the correlated color temperature of the first wavelength conversion layer 130a and is lower than or equal to the correlated color temperature of the second wavelength conversion layer 130b.

As such, the light emitting device including a combination of a plurality of wavelength conversion layers 130a, 130b, 130c in this manner can reduce a color deviation of light between the light emitting devices 100 and can emit light approaching a black body locus (BBL) line, as compared with light emitting devices each including an individual wavelength conversion layer. In other words, a difference in standard deviation of color matching (SDCM) can be reduced through reduction in deviation of the color coordinates between the light emitting devices 100. That is, the color coordinates of the light emitting device spaced apart by a distance greater than or equal to 7 SDCM of the McAdam ellipse can be shifted to color coordinates within 7 SDCM. In other words, it is possible to manufacture a light emitting device having color coordinates that fall within 7 SDCM, that is, 7 steps. More preferably, the light emitting device has 5 SDCM or less, that is, a deviation of 5 steps or less. Still more preferably, the light emitting device has 3 SDCM or less, that is, a deviation of 3 steps or less.

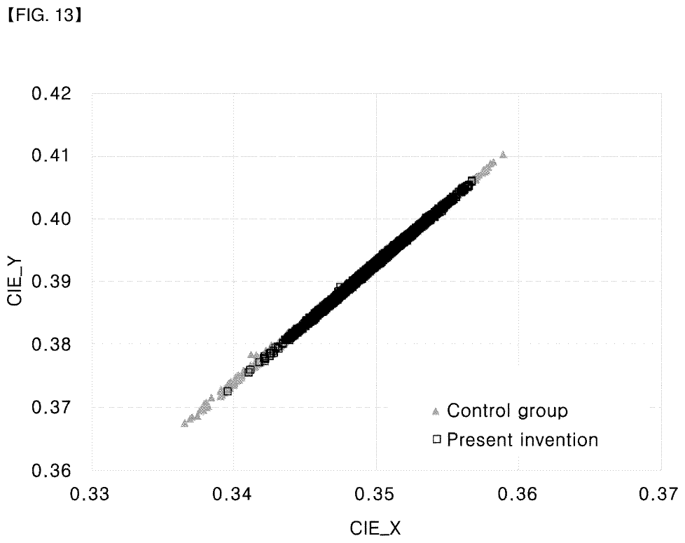

Similarly, FIG. 13 shows a CIE (x, y) color coordinate distribution of a light emitting device including a single wavelength conversion layer 130a, 130b or 130c on an upper surface of one light emitting diode chip 110, and a CIE (x, y) color coordinate distribution of a light emitting device including two wavelength conversion layers 130a, 130b, 130c on an upper surface of one light emitting diode chip 110. From FIG. 13, it can be seen that the light emitting device according to the disclosed technology has a more uniform CIE (x, y) color coordinate distribution. In other words, combination of a wavelength conversion layer having a relatively low color coordinate and a wavelength conversion layer having a relatively high color coordinate in the CIE x or y coordinate can provide a light emitting device including a wavelength conversion layer having a color coordinate closer to a central color coordinate than a light emitting device including a wavelength conversion layer having a higher color coordinate or a light emitting device including a wavelength conversion layer having a lower color coordinate. In other words, the light emitting device including a combination of two or more wavelength conversion layers 130a, 130b, 130c may have a color coordinate located between the color coordinates of a light emitting device including the first wavelength conversion layer alone and a light emitting device including the second wavelength conversion layer alone, or corresponding to a CIE x or y coordinate in a region therebetween. Furthermore, it is possible to provide a light emitting device having a color coordinate that is higher than or equal to a light emitting device having a lower color coordinate and is lower than or equal to a light emitting device having a higher color coordinate among light emitting devices including two or more wavelength conversion layers 130a, 130b, 130c, respectively.

In some implementations, a light emitting device including a combination of a wavelength conversion layer having a lower correlated color temperature and a wavelength conversion layer having a higher correlated color temperature may have a correlated color temperature between the two correlated color temperatures. In other words, a light emitter including two or more wavelength conversion layers having different correlated color temperatures may have a correlated color temperature that is higher than or equal to a correlated color temperature of a light emitting device including the wavelength conversion layer having a lower correlated color temperature and is lower than or equal to a correlated color temperature of a light emitting device including the wavelength conversion layer having a higher correlated color temperature.

In some implementations, the light emitting device including a combination of the plurality of wavelength conversion layers 130a, 130b, 130c in this manner can reduce a color deviation of light between the light emitting devices 100 and can emit light approaching the black body locus (BBL) line, as compared with the light emitting devices each including a separate wavelength conversion layer. In other words, a difference in standard deviation of color matching (SDCM) can be reduced through reduction in deviation of the color coordinates between the light emitting devices 100. Thus, the color coordinates of the light emitting device spaced apart by a distance greater than or equal to 7 SDCM of the McAdam ellipse can be shifted to color coordinates within 7 SDCM. In other words, it is possible to manufacture a light emitting device having color coordinates that fall within 7 SDCM, that is, 7 steps. More preferably, the light emitting device has 5 SDCM or less, that is, a deviation of 5 steps or less. Still more preferably, the light emitting device has 3 SDCM or less, that is, a deviation of 3 steps or less. That is, it is possible to realize a light emitting device having a color temperature closer to a target color temperature.

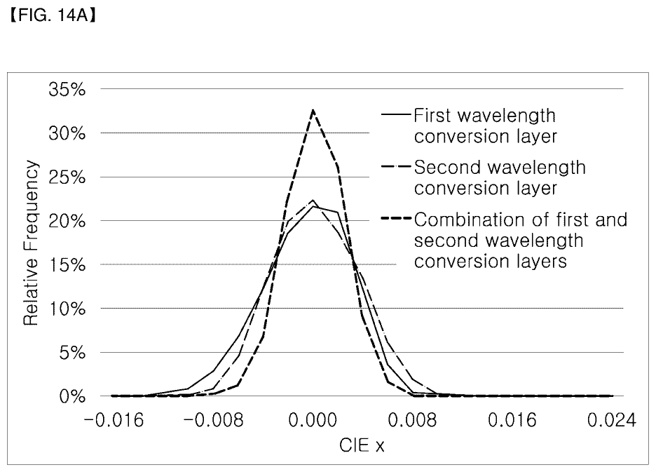

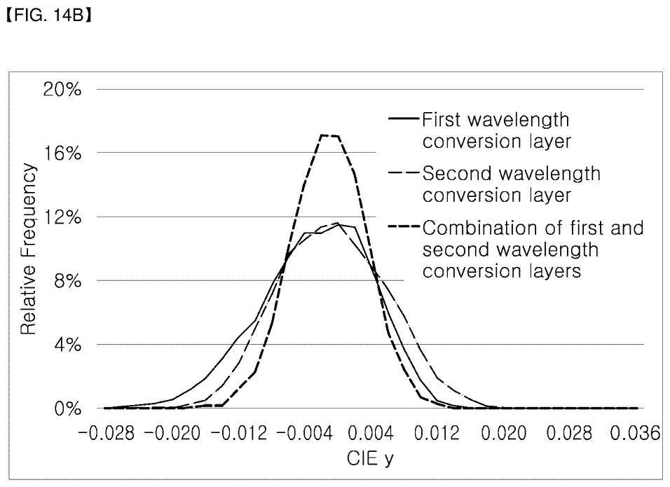

FIG. 14A and FIG. 14B are graphs showing relative frequencies of ΔCIE x and ΔCIE y with reference to target CIE central (x, y) coordinates (for example, (0.23, 0.18)), and show that the deviation of the relative frequencies in the CIE (x, y) color coordinates of the wavelength converter is reduced by combining two wavelength conversion layers 130a, 130b, 130c, for example, the first wavelength conversion layer and the second wavelength conversion layer. In addition, although class intervals of ΔCIE x and ΔCIE y are 0.024 and 0.042 for the first wavelength conversion layer and 0.024 and 0.046 for the second wavelength conversion layer, respectively, it can be seen that combination of the two wavelength conversion layers reduces the class intervals to 0.018 and 0.034, indicating reduction in distribution of the color coordinates. It can be seen that the minimum values of CIE x and CIE y are increased and the maximum values thereof are reduced. In addition, these values approach the center values.

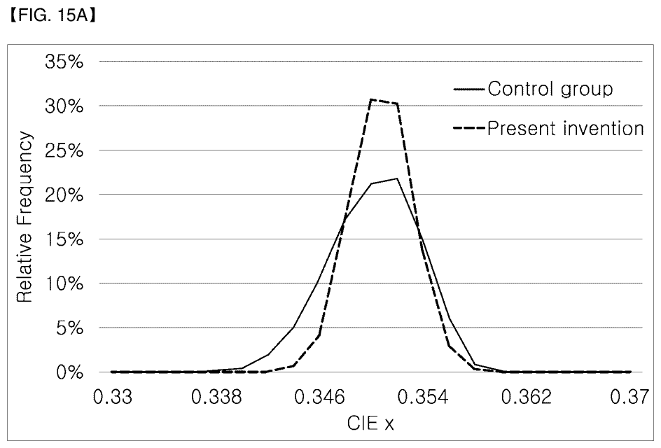

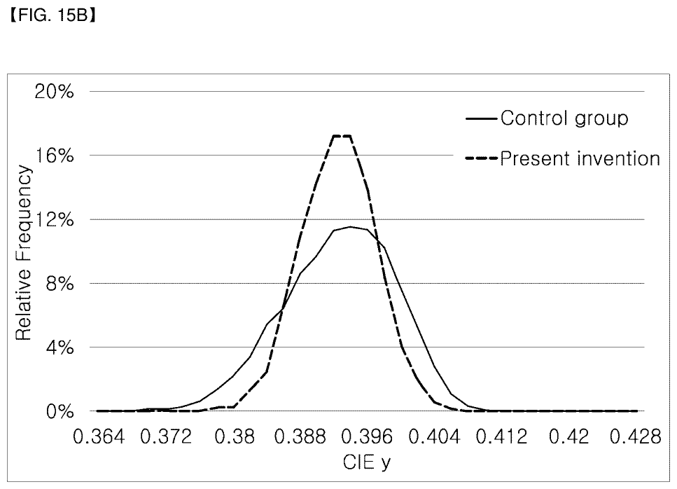

As a result, as shown in FIG. 15A to FIG. 15B, it can be seen that the deviation of the relative frequencies in the CIE (x, y) color coordinates of the light emitting device 100 combining two wavelength conversion layers 130a, 130b, 130c according to the disclosed technology is reduced.

In FIG. 12 to FIG. 15, the two wavelength conversion layers 130a, 130b, 130c are randomly selected and it can be seen that, even when the two wavelength conversion layers 130a, 130b, 130c are randomly combined, it is possible to realize a light emitting device 100 with significantly improved chromatic aberration, compared with a structure in which one wavelength conversion layer 130a, 130b or 130c is applied to one light emitting diode chip 110.

Since the CIE color coordinates of the fluorescent batches S1, S2 over the entire area of the fluorescent batches S1, S2 can be detected and identified in advance, it is possible to manufacture a light emitting device 100 having more uniform light emission characteristics through combination of the plurality of wavelength conversion layers 130a, 130b, 130c to be disposed on the light emitting diode chip 110 based on such pre-identified characteristics data. In the structure where the first wavelength conversion layer located at a relatively low x coordinate in the CIE x coordinate and the second wavelength conversion layer located at a relatively high x coordinate in the CIE x coordinate are disposed in the light emitter or the light emitting diode chip 110, the CIE x coordinate may have an intermediate value between the x coordinates of the first wavelength conversion layer and the second wavelength conversion layer, or a coordinate located between the two coordinates thereof. In addition, in the structure where a first wavelength conversion layer having a CIE x coordinate located at a relatively left side and a second wavelength conversion layer having a CIE x coordinate located at a relatively right side are disposed in the light emitting diode chip 110, the light emitter may have a CIE x coordinate that is higher than or equal to the CIE x coordinate of the first wavelength conversion layer and is lower than or equal to the CIE x coordinate of the second wavelength conversion layer. Further, in the structure where a combination of a first wavelength conversion layer having a relatively low y coordinate in the CIE y coordinate and a second wavelength conversion layer having a relatively high y coordinate in the CIE y coordinate is disposed in the light emitting diode chip 110, the light emitter may have an intermediate CIE y coordinate between the two coordinates or may have a y coordinate in a region therebetween. Furthermore, the light emitter including the combination of the two wavelength conversion layers may have a CIE y coordinate that is higher than or equal to the CIE y coordinate of the first wavelength converter and is lower than or equal to the CIE y coordinate of the second wavelength converter.

Combination of the first wavelength conversion layer having a relatively low correlated color temperature (CCT) with the second wavelength conversion layer having a relatively high correlated color temperature can provide a light emitting device having a correlated color temperature between the correlated color temperatures of the first wavelength conversion layer and the second wavelength conversion layer. That is, it is possible to realize a light emitting device 100 capable of emitting light having a color temperature that is higher than or equal to the correlated color temperature of the excitation light emitted from the first wavelength conversion layer and is lower than or equal to the correlated color temperature of the excitation light emitted from the second wavelength conversion layer. In addition, a region of the light emitter to which the first wavelength conversion layer is applied may have a different color temperature from a region of the light emitter to which the second wavelength conversion layer is applied.

In some implementations, the light emitting device including the combination of the plurality of wavelength conversion layers can reduce a color deviation of light between the light emitting devices 100 and can emit light approaching the black body locus (BBL) line, as compared with the light emitting devices each including a separate wavelength conversion layer. In other words, a difference in standard deviation of color matching (SDCM) can be reduced through reduction in deviation of the color coordinates between the light emitting devices 100. Thus, the color coordinates of the light emitting device spaced apart by a distance greater than or equal to 7 SDCM of the McAdam ellipse can be shifted to color coordinates within 7 SDCM. By way of example, it is possible to realize a light emitting device of 7 SDCM or less through combination of two wavelength conversion layers, in which the first wavelength conversion layer is located at the right of 7 SDCM and the second wavelength conversion layer is located at the left of 7 SDCM. In other words, it is possible to manufacture a light emitting device having color coordinates that fall within 7 SDCM, that is, 7 steps. More preferably, the light emitting device has 5 SDCM or less, that is, a deviation of 5 steps or less. Still more preferably, the light emitting device has 3 SDCM or less, that is, a deviation of 3 steps or less.

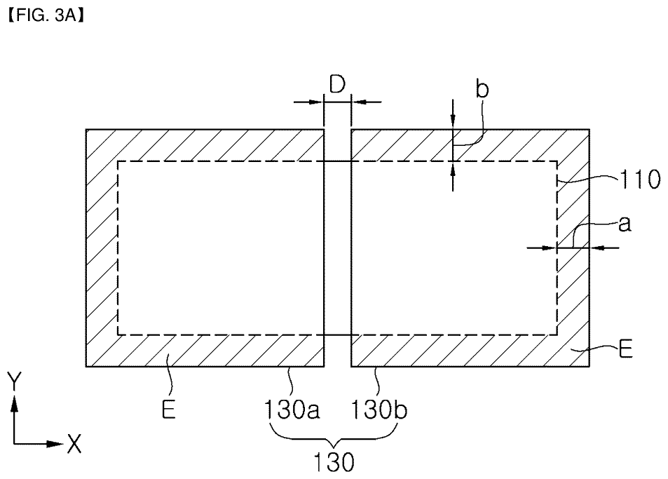

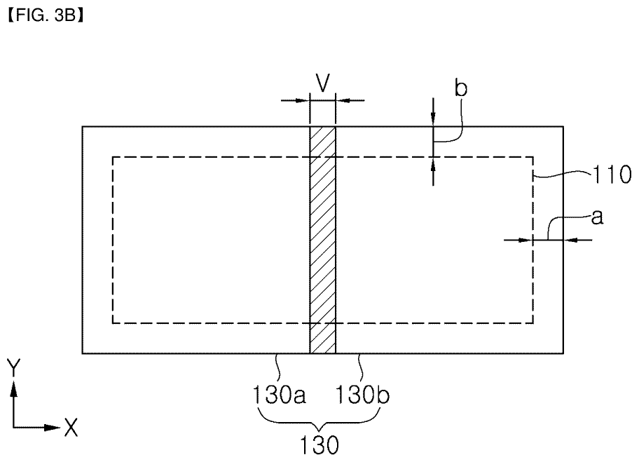

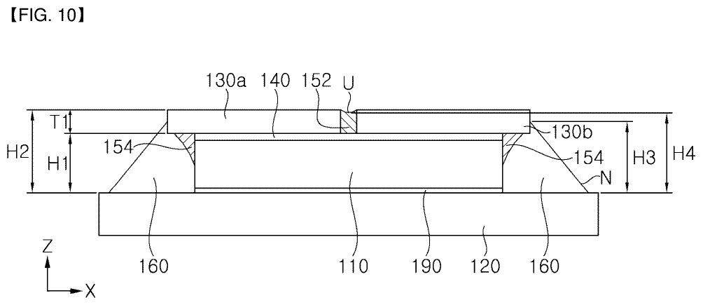

Next, referring to FIG. 3A to FIG. 11B, a light emitting device 100 according to the disclosed technology, in which a plurality of wavelength conversion layers 130a, 130b, 130c is disposed on one light emitting diode chip 110, will be described.

Referring to FIG. 3A, the plurality of wavelength conversion layers 130a, 130b, 130c may be disposed on one light emitting diode chip 110. FIG. 3A illustrates an example in which two wavelength conversion layers 130a, 130b are disposed on an upper surface of one light emitting diode chip 110. However, it should be understood that other implementations are possible.

At least some of the plurality of wavelength conversion layers 130a, 130b, 130c may be disposed on the same plane.

Here, the plurality of wavelength conversion layers 130a, 130b, 130c disposed on one light emitting diode chip 110 may be randomly selected or may be specified according to preset criteria. The wavelength conversion layers 130a, 130b, 130c may have different CIE (x, y) color coordinates. As a result, the wavelength converter 130 may represent the combined color coordinates in an intermediate range of the wavelength conversion layers 130a, 130b, 130c. The light emitting device 100 implemented in this manner may have a CIE x or CIE y coordinate that is higher than or equal to a minimum CIE x or minimum CIE y value of the plurality of wavelength conversion layers 130a, 130b, 130c and is lower than or equal to a maximum CIE x or maximum CIE y value of the plurality of wavelength conversion layers 130a, 130b, 130c.

In some implementations, the light emitting device including the combination of the plurality of wavelength conversion layers 130a, 130b, 130c can reduce a color deviation of light between the light emitting devices 100 and can emit light approaching the black body locus (BBL) line, as compared with light emitting devices each including a separate wavelength conversion layer 130a, 130b or 130c. In other words, a difference in standard deviation of color matching (SDCM) can be reduced through reduction in deviation of the color coordinates between the light emitting devices 100. That is, the color coordinates of the light emitting device spaced apart by a distance greater than or equal to 7 SDCM of the McAdam ellipse can be shifted to color coordinates within 7 SDCM. By way of example, it is possible to realize a light emitting device of 7 SDCM or less through combination of two wavelength conversion layers, in which the first wavelength conversion layer is located at the right of 7 SDCM and the second wavelength conversion layer is located at the left of 7 SDCM. In other words, it is possible to manufacture a light emitting device having color coordinates that fall within 7 SDCM, that is, 7 steps. More preferably, the light emitting device has 5 SDCM or less, that is, a deviation of 5 steps or less. Still more preferably, the light emitting device has 3 SDCM or less, that is, a deviation of 3 steps or less.

In some implementations, the plurality of wavelength conversion layers 130a, 130b, 130c may have the same size, without being limited thereto. Alternatively, at least one of the wavelength conversion layers 130a, 130b, 130c may have a different size than the other wavelength conversion layers 130a, 130b, 130c. For example, the size of the wavelength conversion layer having color coordinates close to the center coordinates may be increased and the size of the wavelength conversion layer having color coordinates apart from the center coordinates may be decreased to reduce the deviation of the color coordinates of the light emitting device 100. Here, the wavelength conversion layer having a smaller size can have less influence on the light emitting device 100 than the wavelength conversion layer having a larger size. In other words, the light emitting device 100 including the combination of the plurality of wavelength conversion layers 130a, 130b, 130c having different sizes may have CIE (x, y) coordinates closer to the coordinates of the wavelength conversion layer having a lager size than the coordinates of the wavelength conversion layer having a smaller size.

In some implementations, the sum of the areas of the plurality of wavelength conversion layers 130a, 130b, 130c disposed on the one light emitting diode chip 110 may be 0.9 to 1.5 times the area of the light emitting diode chip 110. More preferably, the sum of the areas of the plurality of wavelength conversion layers 130a, 130b, 130c disposed on the one light emitting diode chip 110 may be 1.3 times the area of the light emitting diode chip 110. When the sum of the areas of the wavelength conversion layers 130a, 130b, 130c is larger than the area of the light emitting diode chip 110, the area of light passing through the wavelength conversion layers 130a, 130b, 130c may be larger than the area of the light emitting diode chip 110, thereby increasing the quantity of light through improvement in luminous efficacy of the light emitting device 100 due to increase in luminous area. However, if the sum of the areas of the wavelength conversion layers becomes larger than 1.5 times the area of the light emitting diode chip 110, the wavelength conversion layers in a region beyond a light traveling path perform unnecessary wavelength conversion instead of contribution to wavelength conversion, thereby reducing light quality through reduction in color coordinate uniformity according to an angle in a product by reducing the correlated color temperature of lateral light.

The plurality of wavelength conversion layers 130a, 130b, 130c may have the same thickness T1, without being limited thereto. Alternatively, for example, at least one of the wavelength conversion layers 130a, 130b, 130c may have a different thickness T1 than the other wavelength conversion layers 130a, 130b, 130c. Since the color coordinates of the wavelength conversion layers 130a, 130b, 130c tend to shift upwards with increasing thickness thereof, the deviation of the color coordinates of the light emitting device 100 can be reduced by arranging the wavelength conversion layers 130a, 130b, 130c having different thicknesses. For example, combination of a wavelength conversion layer having a relatively thin thickness with a wavelength conversion layer having a relatively thick thickness can realize a light emitter having color coordinates that are higher than color coordinates of a light emitter including a thin wavelength conversion layer alone and are lower than color coordinates of a light emitter including a thick wavelength conversion layer alone.

The wavelength conversion layers 130a, 130b, 130c may have a thickness T1 in the range of 90 micrometers to 200 micrometers and may have different thicknesses T1 depending on the correlated color temperature (CCT). The lower the CCT, the greater the thickness T1 of the wavelength conversion layers 130a, 130b, 130c, and the thinner the thickness T1 of the wavelength conversion layers 130a, 130b, 130c, the higher the quantity of light emitted from the light emitting device. Accordingly, there may be wavelength conversion layer regions with different thicknesses within one light emitting device. In addition, the light emitters including wavelength conversion layers with different thicknesses may have different correlated color temperatures. In some implementations, a light emitter including a wavelength conversion layer in a region having a thin thickness may have a higher correlated color temperature and a light emitter including a wavelength conversion layer in a region having a thick thickness may have a lower correlated color temperature. Further, the wavelength conversion layers with different thicknesses may have different color coordinates. A wavelength conversion layer with a thin thickness may have a lower x or y coordinate than a wavelength conversion layer with a thick thickness. Accordingly, the color coordinates of a light emitter including a combination of a relatively thin wavelength conversion layer and a relatively thick wavelength conversion layer may have an x or y coordinate value that is higher than a light emitter including the relatively thin wavelength conversion layer alone and is lower than a light emitter including the relatively thick wavelength conversion layer alone. For example, the light emitting device may have different standard deviations of color matching depending on the thicknesses of the wavelength conversion layers and a light emitting device having a narrow standard deviation of color matching can be implemented by combining wavelength converters having different thicknesses. In other words, the color coordinates of the light emitting device spaced apart by a distance greater than or equal to 7 SDCM of the McAdam ellipse can be shifted to color coordinates within 7 SDCM. By way of example, it is possible to realize a light emitting device placed near the center of 7 SDCM through combination of two wavelength conversion layers, in which the first wavelength conversion layer has a thick thickness and thus has the color coordinates located at the right of 7 SDCM and the second wavelength conversion layer has a thin thickness and thus has the color coordinates located at the left of 7 SDCM. Thus, it is possible to manufacture a light emitting device having color coordinates that fall within 7 SDCM, that is, 7 steps. More preferably, the light emitting device has 5 SDCM or less, that is, a deviation of 5 steps or less. Still more preferably, the light emitting device has 3 SDCM or less, that is, a deviation of 3 steps or less.

In some implementations, the minimum thickness of the wavelength conversion layers 130a, 130b, 130c may be at least twice the particle size of phosphor particles having the largest size among phosphor particles disposed in any one region of the wavelength conversion layers 130a, 130b, 130c.

In some implementations, the maximum thickness of the wavelength converter 130 may be no greater twice the maximum thickness of the light emitter in which the wavelength converter 130 is disposed. Alternatively, the maximum thickness of the wavelength converter 130 may be less than or equal to twice the maximum thickness of the light emitting diode chip 110 in which the wavelength converter 130 is disposed. Alternatively, the maximum thickness of the wavelength converter 130 may be less than or equal to twice the maximum thickness of the substrate 120 on which the light emitting diode chip 110 including the wavelength converter 130 therein is mounted.

In some implementations, the plurality of wavelength conversion layers 130a, 130b, 130c may be spaced apart from each other in a plane on the upper surface of the light emitting diode chip 110. Although FIG. 3A illustrates an example in which the wavelength conversion layers 130a, 130b, 130c are spaced apart from each other in a longitudinal direction (X-axis direction in the drawing) of a long side of the light emitting diode chip 110, it should be understood that other implementations are possible.

A distance D between adjacent wavelength conversion layers 130a, 130b, 130c may be set in various ways and may be in the range of, for example, 10 micrometers to 50 micrometers, preferably about 30 micrometers in consideration of the sizes of the light emitting diode chip 110 and the wavelength conversion layers 130a, 130b, 130c.

In particular, the plurality of wavelength conversion layers 130a, 130b, 130c may be spaced apart from each other in the light emitting diode chip 110 so as to avoid a region having the highest temperature, thereby improving reliability of the light emitting device 100 through suppression of degradation of the phosphors.

In one modification, the plurality of wavelength conversion layers 130a, 130b, 130c may be disposed in a plane on the upper surface of the light emitting diode chip 110 to partially overlap in a region, as shown in FIG. 3B. In FIG. 3B, the region in which two wavelength conversion layers 130a, 130b, 130c overlap each other is indicated by V. In the structure where the wavelength conversion layers 130a, 130b, 130c are arranged to overlap each other in a region on the upper surface of the light emitting diode chip, the color temperature of the overlapping region becomes lower than the color temperature of a non-overlapping region, thereby reducing chromatic aberration according to beam angle through reduction in color temperature in the overlapping region of the light emitting device 100. In the region in which the wavelength conversion layers 130a, 130b, 130c overlap each other, the wavelength conversion layer has a greater thickness than the wavelength conversion layer in the non-overlapping region, and a path for light passing through the wavelength conversion layers becomes longer, thereby lowering the color coordinates. Thus, the light emitting device may have two or more wavelength conversion layer regions with different thicknesses. In addition, the light emitter may have a lower correlated color temperature in a thick region than in a thin region in which the wavelength conversion layers do not overlap. The overlapping region may be generally a central region of the light emitting diode chip 110, which may correspond to a center of the light emitter, and the correlated color temperature of the center of the light emitter may be lower than that of an outer periphery of the light emitting device.

In another modification, the wavelength conversion layers 130a, 130b, 130c may also be arranged to adjoin each other without a gap therebetween at one side surface thereof. In the structure where the wavelength conversion layers 130a, 130b, 130c are arranged so as not to have an overlapping region, the light emitting device may be designed to have a uniform thickness or not to have an abruptly variable thickness, thereby realizing a color-over-angle (CoA) that varies continuously rather than abruptly.

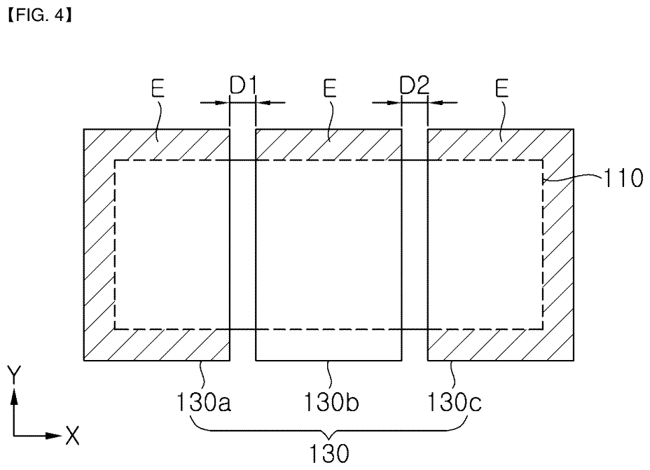

FIG. 4 illustrates an example in which three wavelength conversion layers 130a, 130b, 130c are disposed on one light emitting diode chip 110. In this structure, distances D1, D2 between the three wavelength conversion layers 130a, 130b, 130c may be in the range of, for example, 10 micrometers and 50 micrometers, preferably about 30 micrometers in consideration of the size of the light emitting diode chip 110 and the sizes of the wavelength conversion layers 130a, 130b, 130c. As such, increase in the number of the wavelength conversion layers 130a, 130b, 130c can further narrow chromatic aberration between the light emitting devices 100. By way of example, when the first wavelength conversion layer has the lowest CIE (x, y) coordinates, the second wavelength conversion layer has an intermediate CIE x coordinate and the highest CIE y coordinate, and the third wavelength conversion layer has the highest CIE x coordinate and a CIE y coordinate that is lower than or equal to that of the first or second wavelength conversion layer, the light emitter including a combination of the three wavelength conversion layers may have a higher CIE x coordinate than a light emitter including the first wavelength conversion layer alone and a CIE y coordinate that is lower than that of a light emitter including the second wavelength conversion layer alone and is higher than that of a light emitter including the third wavelength conversion layer alone. In other words, it is possible to realize a light emitter having color coordinates located in a middle region of the CIE (x, y) coordinates of the light emitters including the three wavelength conversion layers, respectively.

In another example, when the first wavelength conversion layer has the highest correlated color temperature, the third wavelength conversion layer has the lowest correlated color temperature, and the second wavelength conversion layer has an intermediate correlated color temperature, the color temperature of the light emitter including the three wavelength conversion layers is lower than the color temperature of the light emitter using the first wavelength conversion layer and higher than the color temperature of the light emitter using the third wavelength conversion layer. Here, the second wavelength conversion layer having a correlated color temperature between the two correlated color temperatures may serve to increase the center coordinates of the color temperature towards the +y axis while improving color uniformity by raising the y coordinate to be close to the BBL (black body locus) line. In other words, the correlated color temperature of the light emitter including at least three wavelength conversion layers may be higher than that of the light emitter including the wavelength conversion layer having the lowest correlated color temperature alone and lower than that of the light emitter including the wavelength conversion layer having the highest correlated color temperature alone.

As such, the light emitting device including the combination of the plurality of wavelength conversion layers can reduce a color deviation of light between the light emitting devices 100 and can emit light approaching the black body locus (BBL) line, as compared with the light emitting devices each including a separate wavelength conversion layer. In other words, a difference in standard deviation of color matching (SDCM) can be reduced through reduction in deviation of the color coordinates between the light emitting devices 100. Thus, the color coordinates of the light emitting device spaced apart by a distance greater than or equal to 7 SDCM of the McAdam ellipse can be shifted to color coordinates within 7 SDCM. By way of example, when the first wavelength conversion layer has color coordinates disposed at the right side with respect to the center of 7 SDCM, the second wavelength conversion layer has color coordinates disposed at the left side with respect to the center of 7 SDCM, and the third wavelength conversion layer has an x coordinate in a region between the x coordinates of the first and second wavelength conversion layers with respect to 7 SDCM and an y coordinate higher or lower than either the first or second wavelength conversion layers, the light emitting device including a combination of the three wavelength conversion layers can have a y coordinate that is located at the left side of the color coordinates of the first wavelength conversion layer, at the right side of the color coordinates of the second wavelength conversion layer, and close to the center of the color coordinates of the third wavelength conversion layer, that is, close to the center of the 7 SDCM. In other words, it is possible to manufacture a light emitting device having color coordinates that fall within 7 SDCM, that is, 7 steps. More preferably, the light emitting device has 5 SDCM or less, that is, a deviation of 5 steps or less. Still more preferably, the light emitting device has 3 SDCM or less, that is, a deviation of 3 steps or less.

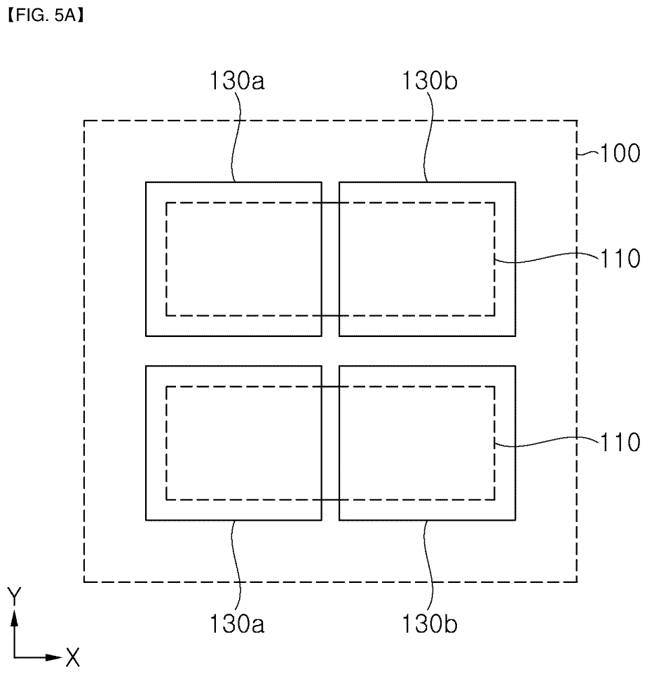

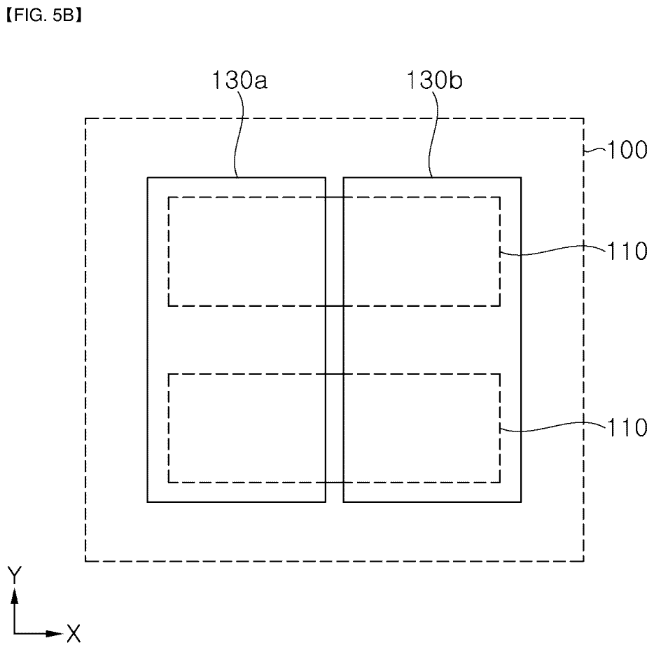

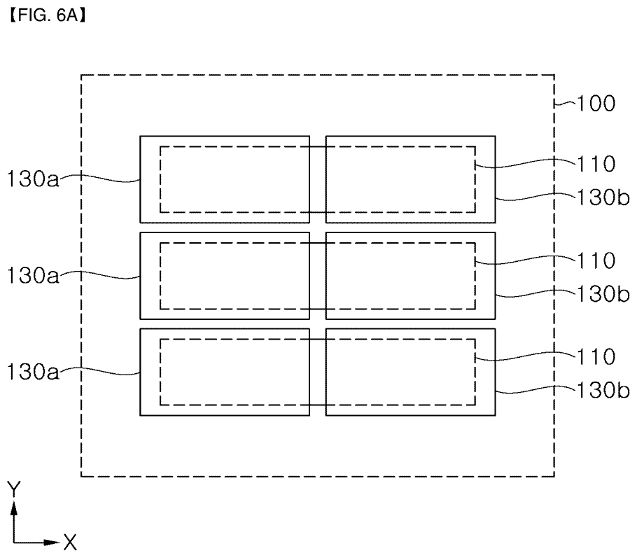

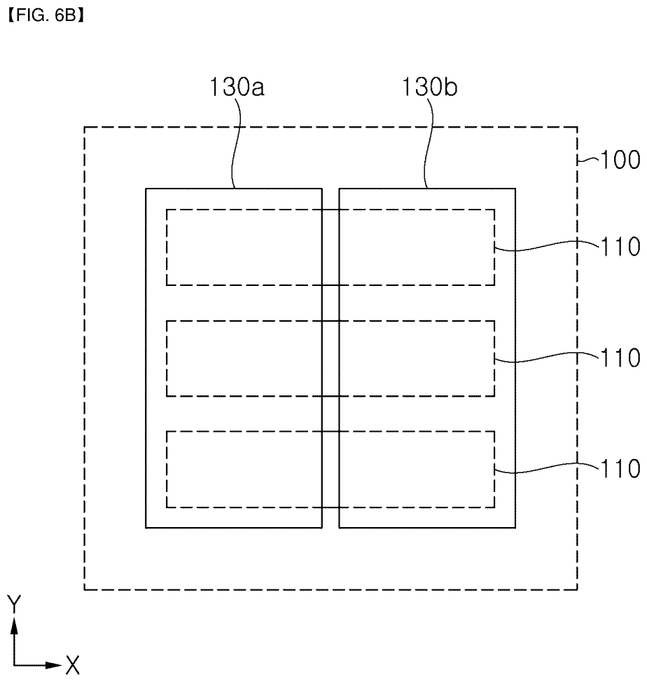

FIG. 5A to FIG. 6B illustrate an example of a light emitting device 100 including a plurality of light emitting diode chips 110, showing a multi-chip structure or light emitting module including two or three light emitting diode chips 110. The plurality of light emitting diode chips 110 may be separately and individually driven by current and voltage control and the light emitting device may further include circuitry for current and voltage control.

When operation of each of the plurality of light emitting diode chips 110 is controlled, various colors with color coordinates disposed between the color coordinates of two or more light emitters can be expressed. For example, among the light emitters including independently operable light emitting diode chips 110, one light emitter may have a correlated color temperature of a warm white color between 3,800 K and 1,300 K and another light emitter may have a correlated color temperature of a cool white color between 5,000 K and 7,000 K, thereby realizing the light emitting device 100 that emits light having a correlated color temperature between 1,300 K and 7,000 K through control of operation of the two or more light emitters. Here, when the two or more light emitters are operated simultaneously, the light emitting device 100 may have a correlated color temperature higher than 1,300 K and lower than 7,000 K. More preferably, the light emitters may have a correlated color temperature between 3000K, 4000K, and 5000K. Further, operation of the light emitters may be controlled by current or may be controlled by increasing or decreasing the ratio of duty cycle of each of the light emitters. For example, when the ratio of duty cycle of a first light emitter having a low correlated color temperature and the ratio of duty cycle of a second light emitter having a high correlated color temperature are adjusted to 50%, the light emitting device 100 can emit light having a correlated color temperature between the correlated color temperatures of the first light emitter and the second light emitter. Alternatively, the light emitting device may emit light having a desired correlated color temperature by variously adjusting the ratio of duty cycle of the first light emitter and the second light emitter to 20:80, 40:60, 60:40, 80:20, and the like.

The plurality of light emitting diode chips 110 may be arranged in one direction within the light emitting device 100 or may be arranged at predetermined intervals to be spaced apart from each other. Preferably, the distance between adjacent light emitting diode chips 110 is set to 50 micrometers or more.

In the structure where the light emitting diode chips 110 are spaced apart from each other in the light emitting device 100, the light emitting device 100 can secure lateral luminous areas of the light emitting diode chips 110, thereby increasing the quantity of light emitted from the light emitting device 100. Preferably, the light emitting diode chips 110 are arranged to have a narrower distance therebetween than a length of a major axis of the light emitting diode chips 110.

In the light emitting device 100 of the multi-chip structure, each of the wavelength conversion layers 130a, 130b, 130c may be disposed corresponding to only one diode chip 110, as shown in FIG. 5A or FIG. 6A, or may be disposed corresponding to the plurality of diode chips 110, as shown in FIG. 5B or FIG. 6B.

In the structure where each of the wavelength conversion layers 130a, 130b, 130c is disposed corresponding to only one light emitting diode chip 110 as shown in FIG. 5A or FIG. 6, the wavelength conversion layers 130a, 130b, 130c may be arranged according to the wavelength of each of the light emitting diode chips 110, thereby reducing the deviation of the color coordinates of the light emitting device 100. As a result, it is possible to realize a light emitting device 100 capable of adjusting the color temperature by differently arranging the color coordinates of each of the light emitting diode chips. For example, one light emitter may have a correlated color temperature of a warm white color between 3,800 K and 1,300 K and another light emitter may have a correlated color temperature of a cool white color between 5,000 K and 7,000 K, and the light emitting device 100 may emit light having a correlated color temperature of higher than 1,300 K and lower than 7,000 K through control of the ratio of duty cycle of the light emitters.

In addition, in the structure where each of the wavelength conversion layers 130a, 130b, 130c is disposed corresponding to the plurality of light emitting diode chips 110 as shown in FIG. 5B or FIG. 6B, the manufacturing process can be simplified by reducing the number of processes for bonding the wavelength conversion layers 130a, 130b, 130c, thereby reducing production costs.

When the number of light emitting diode chips 110 disposed in one light emitting device 100 is denoted by Q and the number of wavelength conversion layers 130a, 130b, 130c therein is denoted by Z, the light emitting device can maximize the effect of increasing mass production yield through reduction of scattering of phosphor characteristics when Z is equal to twice as much as Q, and the light emitting device can secure a relatively easy process when Z is less than twice as much as Q.

Further, the wavelength conversion layers 130a, 130b, 130c may form an extension E that protrudes beyond the outer periphery of the light emitting diode chip 110.

The extension E serves not only to reduce the color deviation according to a beam angle through reduction in chromatic aberration of lateral light emitted from the light emitting device 100 by changing the color coordinates of lateral light of the light emitting diode chips 110 through the wavelength conversion layers 130a, 130b, 130c, but also to increase the quantity of light through improvement in luminous efficacy of the light emitting device 100 by providing a larger luminous area of the light emitting device 100 than the areas of the light emitting diode chip 110.

Referring to FIG. 3A, in the extension E, the wavelength conversion layers 130a, 130b, 130c may protrude beyond the outer periphery of the light emitting diode chip 110 by a length a in the longitudinal direction (X-axis direction in the drawing) of the light emitting diode chip 110 and protrude beyond the outer periphery of the light emitting diode chip 110 by a length b in the transverse direction (Y-axis direction in the drawing) perpendicular to the longitudinal direction. The extension E may be a region at least partially surrounding the outer periphery of the light emitting diode chip 110.

Each of the lengths a, b protruding beyond the outer periphery of the light emitting diode chip 110 in the extension E may have a value between 5 micrometers and 50 micrometers, more preferably about 30 micrometers.

It should be understood that the lengths a, b may be the same or different.

When the lengths a, b are the same, the wavelength conversion layers 130a, 130b, 130c have the same size to allow operation without directional distinction, thereby facilitating the manufacturing process.

When the lengths a, b are different, the length of the extension in a direction providing a wide beam angle according to a beam pattern of the light emitting diode chip 110 may be set to be greater than the length of the extension in the other direction, thereby improving luminous efficacy while increasing the quantity of light through increase in luminous area.

The plurality of wavelength conversion layers 130a, 130b, 130c may be attached to the upper surface of the light emitting diode chips 110 via a bonding material and the light emitting device 100 according to the disclosed technology may further include a film adhesive layer 140 interposed between the plurality of wavelength conversion layers 130a, 130b, 130c and the light emitting diode chips 110, which adheres the plurality of wavelength conversion layers 130a, 130b, 130c thereto.

The adhesive material may be deposited to the upper surfaces of the light emitting diode chips 110, followed by attaching the plurality of wavelength conversion layers 130a, 130b, 130c thereto, thereby forming the film adhesive layer 140. The adhesive material forming the film adhesive layer 140 may include a thermosetting or UV-curable resin, such as an urethane resin or an epoxy resin, a transparent bonding agent (for example, phenyl silicone, methyl silicone, or others), such as a sealant or others.

The adhesive material may further include fillers for a light control function, such as light reflection, light absorption, or others, and may further include at least one phosphor. The fillers can improve bonding strength of the film adhesive layer 140.

After being bonded by the film adhesive layer 140, the upper surfaces of the wavelength conversion layers 130a, 130b, 130c may be coplanar with each other. Alternatively, the upper surfaces of the wavelength conversion layers 130a, 130b, 130c may have different heights.

When the upper surfaces of the wavelength conversion layers 130a, 130b, 130c are coplanar with each other, the wavelength conversion layers provide the same light traveling path, thereby providing a uniform light angle or angle of projection. In addition, the heights of the upper surfaces of the wavelength conversion layers 130a, 130b, 130c may be adjusted differently corresponding to light emission patterns of the light emitting diode chips 110 to reduce chromatic aberration in the light emitting device 100.

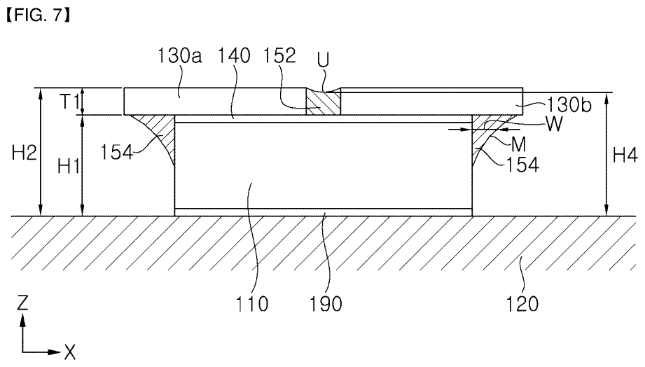

Here, the light emitting device 100 according to the disclosed technology may further include an upper light controller 152 formed in a space between the adjacent wavelength conversion layers 130a, 130b, 130c, as shown in FIG. 7.

In addition, the light emitting device 100 according to the disclosed technology may further include a side light controller 154 formed on a side surface of the light emitting diode chip 110.

The upper light controller 152 and the side light controller 154 may be formed of an adhesive material which adheres the plurality of wavelength conversion layers 130a, 130b, 130c to the upper surface of the light emitting diode chip 110.

Specifically, since adjacent wavelength conversion layers 130a, 130b, 130c are spaced apart from each other by predetermined distances D, D1, D2 in a plane, an empty space may be formed between the adjacent wavelength conversion layers 130a, 130b, 130c, and when the wavelength conversion layers 130a, 130b, 130c are bonded to the upper surface of the light emitting diode chip 110, the adhesive material applied to the upper surface of the light emitting diode chip 110 may be pushed into the corresponding space before curing and then cured to form the upper light controller 152.

In a similar manner, since the wavelength conversion layers 130a, 130b, 130c form the extension E protruding beyond the outer periphery of the light emitting diode chip 110, a space may be formed between the extension E of the wavelength conversion layers 130a, 130b, 130c and the side surface of the light emitting diode chip 110, and when the wavelength conversion layers 130a, 130b, 130c are bonded to the upper surface of the light emitting diode chip 110, the adhesive material applied to the upper surface of the light emitting diode chip 110 may be pushed into the corresponding space and then cured to form the side light controller 154.

First, since the adhesive material is a flowable material before curing, an upper surface U of the upper light controller 152 may form a curved surface, preferably a concave or convex surface.

In the structure where the upper surface U forms a concave surface, light emitted from the light emitting diode chip 110 may be directed from the concave surface to reenter the wavelength conversion layers 130a, 130b, 130c, thereby improving color uniformity through increase in wavelength conversion efficiency. In the structure where the upper surface U forms a convex surface, light emitted from the light emitting diode chip 110 may be emitted from the curved surface, thereby increasing the quantity of light through reduction in total reflection towards a lower surface of the light emitting device.

The maximum point of the upper surface U of the upper light controller 152 may be coplanar with or placed below the upper surfaces of the adjacent wavelength conversion layers 130a, 130b, 130c. In the structure where the upper surface U is coplanar with the upper surfaces of the wavelength conversion layers 130a, 130b, 130c, a fraction of light emitted from the light emitting diode chip 110 and not subjected to wavelength conversion may reenter the wavelength conversion layers 130a, 130b, 130c through total reflection by the surface of the upper light controller 152 to improve wavelength conversion efficiency, thereby improving color uniformity. The thickness of the upper light controller 152 and the curvature of the upper surface U thereof may vary depending on the amount of adhesive material applied to the upper surface of the light emitting diode chip 110.

The adhesive material forming the upper light controller 152 may further include a phosphor or diffusing agent to reduce deviation of the color temperature (CCT) at a central viewing angle (horizontal and vertical, X and Y in FIG. 3 to FIG. 6). Generally, there is a problem that the CCT is highest at a center of the light emitting diode chip 110 and lowest at an outer periphery thereof. Accordingly, the upper light controller 152 placed in a central region of the light emitting diode chip 110 and including the phosphor can reduce the CCT at the central viewing angle and the deviation of the CCT at the overall viewing angles through relative reduction in CCT difference between the central region and the outer periphery. For example, the upper light controller 152 may have a lower color temperature than the wavelength conversion layers 130a, 130b in order to reduce the correlated color temperature at the central viewing angle. In addition, a region of the upper light controller 152 may have a higher phosphor distribution or density than the wavelength conversion layers 130a, 130b, without being limited thereto. Alternatively, a region of the upper light controller 152 may have a lower phosphor density than the wavelength conversion layers 130a, 130b. In this embodiment, the upper light controller 152 can have a higher color temperature than the wavelength conversion layers 130a, 130b and can have relatively high bonding strength.

Accordingly, regions of the upper surface of the light emitting device 100 may have different phosphor distributions, in which the density may be a ratio of an area occupied by phosphor powder to unit area. In other words, a high density may mean that the area occupied by wavelength conversion particles is large relative to an area occupied by the resin. For example, a phosphor powder having a small particle size may be contained as a larger number of powder grains in the resin, while a phosphor powder having a large particle size may be contained as a small number of powder grains in the resin while occupying a large area relative to the area occupied by the resin, indicating a high density.

Similarly, the side light controller 154 may form an inclined surface M on an outward side surface of the light emitting diode chip 110, as shown in FIG. 7.

The inclined surface M may form a curved surface, which may form a concave surface recessed toward the light emitting diode chip 110.

Preferably, the side light controller 154 is confined within an extension region E on a lower surface of the wavelength conversion layer 130a, 130b, 130c so as not to invade a side surface of the wavelength conversion layer 130a, 130b, 130c.

In addition, the height and curvature of the inclined surface M of the side light controller 154 may vary depending on the amount of adhesive material applied to the upper surface of the light emitting diode chip 110.

Furthermore, as the side light controller 154 forms the inclined plane M, the side light controller 154 may have a variable width w that varies from top to bottom. Although the width w may gradually decrease from top to bottom, the width w may also increase in at least a section thereof. For the light emitting device, the amount of light may increase with increasing width w of the side light controller 154, whereas the color-over-angle (CoA) may increase with decreasing width w. In other words, a difference in color temperature between a center of the light emitting device 100 and a side surface of the light emitting device 100 may be 4,000 K or less, or a difference in diagonal distance of the color coordinates may be narrowed.

Although the side light controller 154 may extend to a lower end of the side surface of the light emitting diode chip 110, it is desirable that the side light controller 154 be formed to at least partially expose the side surface of the light emitting diode chip 110, as shown in FIG. 7. That is, the thickness of the side light controller 154 may be less than the thickness of the light emitting diode chip 110.

Specifically, the side light controller 154 may have a height in the range of 5% to 100% of the thickness of the light emitting diode chip 110. The quantity of light emitted from the light emitting device may increase with increasing thickness of the side light controller 154, whereas the color-over-angle (CoA) of the light emitting device may increase with decreasing thickness thereof.

The upper surface light control part 152 may control the light traveling path through refraction and reflection of light emitted from the upper surface of the light emitting diode chip 110, or may emit light after absorbing or converting light through the fillers or the phosphor.

The side light controller 154 may control the light traveling path through refraction and reflection of light emitted from the side surface of the light emitting diode chip 110, or may emit light after absorbing or converting light through the fillers or the phosphor.

The quantity of light emitted from the light emitting device increases with increasing size of the side light controller 154 (with increasing amount of the adhesive material), and reflectivity can be improved by the fillers added to the adhesive material.

The upper light controller 152 and the side light controller 154 maximize efficiency of light emitted from the upper surface of the light emitting diode chip 110 and improve color clarity while reducing chromatic aberration of the light emitting device. Furthermore, the light emitting device 100 according to the disclosed technology may further include a side reflector 160 formed on a side surface of the light emitting diode chip 110 to reflect light emitted from the side surface of the light emitting diode chip 110.

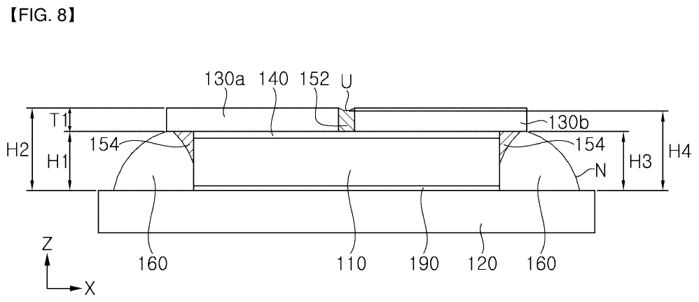

The side reflector 160 is a reflective layer that surrounds the side surface of the light emitting diode chip 110, as shown in FIG. 8, and may have various configurations.

In a structure where the side light controller 154 partially exposes the side surface of the light emitting diode chip 110, the side reflector 160 may adjoin the exposed side surface of the light emitting diode chip 110. In a structure where the light emitting device 100 does not include the side light controller 154, the side reflector 160 may be formed to surround the light emitting diode chip 110 by adjoining almost the entirety of the side surface of the light emitting diode chip 110, preferably the entire side surface thereof.

The side reflector 160 may form an inclined surface N on an outward side surface of the light emitting diode chip 110.

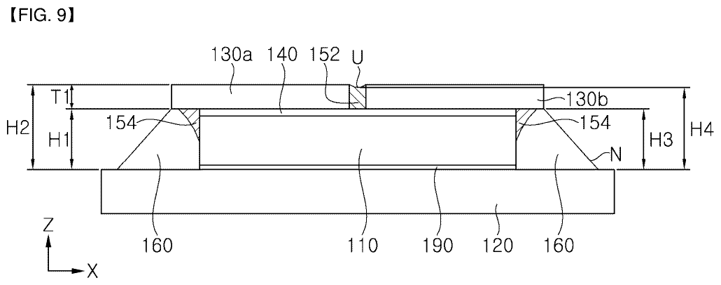

Referring to FIG. 8, the inclined surface N of the side reflector 160 may form a convex surface, without being limited thereto. Alternatively, the inclined surface N of the side reflector 160 may form an oblique surface, as shown in FIG. 9, or may form a recessed concave surface, although not shown in the drawings.

In a structure where the inclined surface N of the side reflector 160 forms a protruding concave or convex surface, light subjected to wavelength conversion by the wavelength conversion layers 130a, 130b, 130c can be reflected towards the side surface of the side reflector 160 to widen the beam angle of the light emitting device 100 while reducing reentrance into the wavelength conversion layers 130a, 130b, 130c, thereby widening the beam angle while reducing chromatic aberration of the light emitting device 100 depending on the beam angle.

In a structure where the inclined surface N of the side reflector 160 forms an oblique surface, the light can be reflected upwards without widening the beam angle to reduce the chromatic aberration of the light emitting device 100 depending on the beam angle.

The side reflector 160 may be formed of a material that contains light reflective particles in a UV-curable or thermosetting resin (for example, a resin containing TiO₂, BaSO₄, or others in silicone), whereby the resin forming the side reflector 160 can fill a space formed between the light emitting diode chip 110 and the substrate 120.

A maximum height H3 of the side reflector 160 from an upper surface of the substrate 120 may be greater than or equal to a height H1 from the upper surface of the substrate 120 to the lower surface of the wavelength conversion layers 130a, 130b, 130c, and as the maximum height H3 of the side reflector 160 increases, light reflectivity of the side reflector 160 increases, thereby increasing the quantity of light.

In addition, the maximum height H3 of the side reflector 160 from the upper surface of the substrate 120 may be lower than a height H2 from the upper surface of the substrate 120 to the upper surface of the wavelength conversion layers 130a, 130b, 130c. When the maximum height H3 of the side reflector 160 is higher than the height H2 from the upper surface of the substrate 120 to the upper surface of the wavelength conversion layers 130a, 130b, 130c, the side reflector 160 can extend to the upper surface of the wavelength conversion layer 130a, 130b, 130c, thereby causing decrease in quantity of light.

That is, the maximum height H3 of the side reflector 160 from the upper surface of the substrate 120 may be located between the height H1 of the substrate 120 from the upper surface of the substrate 120 to the lower surface of the wavelength converter 130 and the height H2 of the wavelength converter 130 from the upper surface of the substrate 120 to the upper surface of the wavelength converter 130.

Furthermore, in the structure where the light emitting device 100 includes the upper light controller 152, the maximum height H3 of the side reflector 160 from the upper surface of the substrate 120 may be lower than a height H4 from the upper surface of the substrate 120 to the lowest point of the upper surface U of the upper light controller 152. This structure can prevent the side reflector 160 from invading a light emitting area and decreasing the quantity of light.

On the other hand, the structure where the height H3 of the side reflector 160 is located below the lower surface of the wavelength conversion layer 130a, 130b, 130c or the upper surface of the light emitting diode chip 110 has structural stability.

In addition, since the reflectivity of the side reflector 160 can increase with increasing thickness of the side reflector 160 and the light traveling path varies depending on an inclination of the inclined surface N, the angle of reflection may be adjusted by adjusting the thicknesses of the side reflector 160 and the curvature of the inclined surface N.

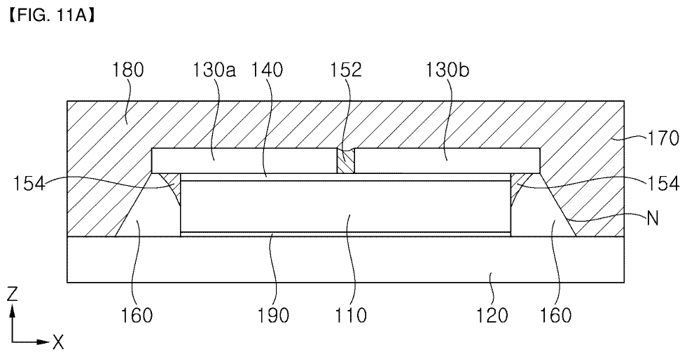

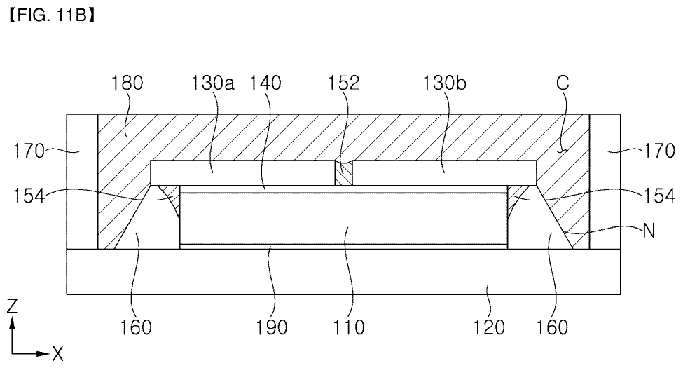

Next, referring to FIG. 11A and FIG. 11B, the light emitting device 100 may further include a lens layer 180 that covers the light emitting diode chip 110, the substrate 120, and the wavelength converter 130.

The lens layer 180 is a kind of molding layer and may be formed of a UV-curable or thermosetting transparent resin, without being limited thereto. In particular, the lens layer 180 may be formed of a material having an index of refraction between 1.3 and 1.6 to relieve a difference in index of refraction when light emitted from the light emitter and the wavelength converter 130 exits into the air, thereby increasing the quantity of light emitted from the light emitting device 100 through improvement in extraction efficiency of light.

The lens layer 180 may further include additives, such as silicon oxide, titanium oxide, barium titanate, barium oxide, aluminum oxide, or others, as a diffusing agent, to diffuse light such that light emitted from the wavelength conversion layers 130a, 130b, 130c is mixed with light emitted from the upper light controller 152 to reduce color deviation depending on the beam angle of the light emitting device 100. In the lens layer 180, the concentration of the diffusing agent may be smaller than the concentration of the particles in the wavelength converter 130 in order to improve light extraction efficiency. In other words, the particles contained in the lens unit 180 may have a smaller surface area than the particles contained in the wavelength converter 130.

In addition, addition of the aforementioned fluorescent materials to the lens unit 180 allows additional adjustment of the color coordinates through secondary excitation of light having passed through the wavelength converter 130, thereby realizing a light emitting device 100 securing higher quality of color reproduction. In other words, the light having passed through the wavelength converter 130 may be excited once again to approach the black body locus (BBL) line by the fluorescent materials through adjustment of the color coordinates to reduce the standard deviation of color matching. In other words, the standard deviation of color matching (SDCM) can be reduced by reducing the deviation between the light emitting devices 100. That is, the color coordinates of the light emitting device spaced apart by a distance greater than or equal to 7 SDCM of the McAdam ellipse can be shifted to color coordinates within 7 SDCM. For example, for the light emitter having 7 SDCM or more, the lens layer 180 may further include the fluorescent material to adjust the standard deviation of color matching. For example, a light emitter having color coordinates at the right side of 7 SDCM may be adjusted by adding the fluorescent material to the lens layer 180 to shift the color coordinates to the left side of the existing light emitter so as to be placed within 7 SDCM. Conversely, a light emitter having color coordinates at the left side of 7 SDCM may be adjusted by the fluorescent material to shift the color coordinates to the right side so as to be placed within 7 SDCM. In other words, it is possible to manufacture a light emitting device having color coordinates that fall within 7 SDCM, that is, 7 steps. More preferably, the light emitting device has 5 SDCM or less, that is, a deviation of 5 steps or less. Still more preferably, the light emitting device has 3 SDCM or less, that is, a deviation of 3 steps or less. The lens layer 180 may have a lower concentration of phosphor particles than the wavelength converter 130 in order to improve light extraction efficiency. In other words, the phosphor particles contained in the lens unit 180 may have a smaller surface area than the phosphor particles contained in the wavelength converter 130.

Further, in order to reduce light loss, the lens layer 180 may have a thickness that is greater than the thickness of the light emitting diode chip 110 and is greater than or equal to the sum of the thicknesses of the light emitting diode chip 110 and the wavelength converter 130. If the thickness of the lens layer 180 is lower than the height of the light emitting diode chip 110, the light emitting device can suffer from deterioration in light extraction efficiency, and if the lens layer 180 has too thick a thickness, light absorption can occur inside the lens layer 180. Accordingly, the lens layer 180 is required to have an appropriate height. Furthermore, the lens layer 180 may further include a curvature or roughness to improve luminous efficacy and may include a Fresnel lens or an optical design to adjust the beam angle or light emission angle. The lens layer is not limited to a specific shape and may be formed in various shapes.

Referring to FIG. 11B, the light emitting device 100 may further include a sidewall 170 defining a cavity C for mounting the light emitting diode chip 110.

Although FIG. 11B shows an example in which the lens layer 180 is formed in the cavity C defined by the sidewall 170, it should be understood that other implementations are possible. The lens layer 180 is provided as an optional component and may be omitted.

The sidewall 170 is a wall member surrounding the outer periphery of the light emitting diode chip 110. The sidewall 170 has an inner surface capable of acting as a reflective surface and can protect the light emitter from an external environment.

The sidewall 170 may have a greater height than the wavelength converter 130 and the inner surface of the sidewall 170 may form an inclined surface. The height of the sidewall 170 may be lower than the sum of the thicknesses of the wavelength converter 130 and the light emitting diode chip 110.

Although FIG. 11B shows an example in which the inner surface of the sidewall 170 forms a vertical surface such that the inner surface of the sidewall 170 has a constant horizontal width, the inner surface of the sidewall 170 may form an inclined surface so as to have a horizontal width gradually increasing in an upward direction. With the inner surface having a horizontal width gradually increasing in the upward direction, the sidewall 170 can reflect light incident on the sidewall 170 to the top of the light emitting device 100, thereby increasing the quantity of light.

In addition, the light emitting device may further include a separate cover member or lens member at an upper end of the sidewall to open or close an upper opening of the sidewall 170 so as to adjust the beam angle.

On the other hand, in the light emitting device 100, the upper light controller 152, the side light controller 154, the side reflector 160, the lens layer 180, and the sidewall 170 may be combined in various ways. That is, the light emitting device 100 according to the disclosed technology may include the light emitting diode chip 110, the substrate 120, and the wavelength converter 130 as a basic structure, and may further include at least one of the upper light controller 152, the side light controller 154, the side reflector 160, the lens layer 180, and the sidewall 170 in various combinations.

Although some exemplary embodiments have been described herein with reference to the accompanying drawings, it should be understood that various modifications and changes can be made by those skilled in the art or by a person having ordinary knowledge in the art without departing from the spirit and scope of the present disclosure, as defined by the claims and equivalents thereto.

Therefore, the scope of the present disclosure should be defined by the appended claims and equivalents thereto rather than by the detailed description of the present disclosure.

1. A light emitting device, comprising:
a substrate forming a mounting region;
a light emitting diode chip mounted in the mounting region;
a wavelength converter disposed on an upper surface of the light emitting diode chip,
wherein the wavelength converter includes a plurality of wavelength conversion layers, at least some of the plurality of wavelength conversion layers being disposed on a same plane.

2. The light emitting device according to claim 1, further comprising:
a film adhesive layer disposed between the plurality of wavelength conversion layers and the light emitting diode chip, the film adhesive layer configured to adhere the plurality of wavelength conversion layers to the light emitting diode chip.

3. The light emitting device according to claim 1, further comprising:
an upper light controller disposed in a space between two adjacent ones of the plurality of wavelength conversion layers.

4. The light emitting device according to claim 3, wherein an upper surface of the upper light controller includes a concave surface.

5. The light emitting device according to claim 1, further comprising:
a side light controller disposed on a side surface of the light emitting diode chip.

6. The light emitting device according to claim 5, wherein the plurality of wavelength conversion layers form an extension protruding beyond an outer periphery of the light emitting diode chip, and the side light controller is disposed in a space between the extension and the side surface of the light emitting diode chip.

7. The light emitting device according to claim 5, wherein the side light controller has a variable width (w) which varies from top to bottom.

8. The light emitting device according to claim 5, wherein the side light controller forms an inclined surface on its outward side surface.

9. The light emitting device according to claim 1, further comprising:
a lens layer covering the light emitting diode chip, the substrate and the wavelength converter.

10. The light emitting device according to claim 1, further comprising:
a side reflector disposed on a side surface of the light emitting diode chip and configured to reflect light emitted from the side surface of the light emitting diode chip.

11. The light emitting device according to claim 10, wherein a maximum height of the side reflector from an upper surface of the substrate is between a height from the upper surface of the substrate to a lower surface of the wavelength converter and a height from the upper surface of the substrate to an upper surface of the wavelength converter.

12. The light emitting device according to claim 1, further comprising:
a sidewall defining a cavity for mounting the light emitting diode chip.

13. A light emitting device, comprising:
a substrate providing a mounting region;
a light emitting diode chip disposed in the mounting region;
a wavelength converter disposed on an upper surface of the light emitting diode chip,
wherein the wavelength converter includes a plurality of wavelength conversion layers forming an extension protruding beyond an outer periphery of the light emitting diode chip.

14. The light emitting device according to claim 13, further comprising:
a side light controller disposed on a side surface of the light emitting diode chip.

15. The light emitting device according to claim 14, wherein the side light controller is disposed in a space between the extension and the side surface of the light emitting diode chip.

16. A light emitting device, comprising:
a light emitter;
a substrate providing a mounting region where the light emitter is mounted; and
a wavelength converter disposed on an upper surface of the light emitter and configured to convert a wavelength of light emitted from the light emitter,
wherein the wavelength converter comprises a plurality of wavelength conversion layers, and
first excitation light and second excitation light emitted from two of the plurality of wavelength conversion layers, respectively, have different color coordinates from each other.

17. The light emitting device according to claim 16, wherein the wavelength converter is configured to represent combined color coordinates of the wavelength conversion layers.

18. The light emitting device according to claim 16, wherein the first excitation light and the second excitation light have a color temperature of K=449n³+3525n²−6823.3n+5520.33, where
$$n = \frac{( x - 0.332 )}{( y - 0.1858 )} ,$$
and a difference between a first K value of the first excitation light and a second K value of the second excitation light is less than or equal to 1,000.

19. The light emitting device according to claim 16, wherein the light emitter includes a plurality of light emitting diode chips.

20. The light emitting device according to claim 19, wherein each of the plurality of light emitting diode chips is individually operable from one another.
